(19) United States
(12) Patent Application Publication
(10) Pub. No.: US 2025/0040154 A1
(43) Pub. Date: Jan. 30, 2025

(54) SEMICONDUCTOR DEVICES

(71) Applicant: SAMSUNG ELECTRONICS CO., LTD., Suwon-si (KR)

(72) Inventors: Hakseon KIM, Suwon-si (KR); Dongjin LEE, Suwon-si (KR); Jaeduk LEE, Suwon-si (KR); Kangoh YUN, Suwon-si (KR)

(21) Appl. No.: 18/624,857

(22) Filed: Apr. 2, 2024

(30) Foreign Application Priority Data
Jul. 24, 2023 (KR) 10-2023-0096409

(51) Int. Cl. H10B 80/00; H01L 23/00; H01L 25/065; H01L 25/18; H10B 41/27; H10B 41/41; H10B 43/27; H10B 43/40

(52) U.S. Cl. CPC H10B 80/00; H01L 24/06; H01L 24/08; H01L 25/0657; H01L 25/18; H10B 41/27; H10B 41/41; H10B 43/27; H10B 43/40; H01L 2224/06517; H01L 2224/08146; H01L 2924/1431; H01L 2924/14511

(57) ABSTRACT

A semiconductor device includes a peripheral circuit structure; and a cell structure on the peripheral circuit structure, wherein the peripheral circuit structure comprises: a substrate comprising a cell region, a connection region adjacent to the cell region, and a pad region extending around the cell region and the connection region; a first connection structure between the substrate and the cell structure; a first peripheral circuit transistor in the cell region and/or the connection region; and a second peripheral circuit transistor in the pad region, wherein the first connection structure includes a first wiring structure and a dummy structure, the first wiring structure is electrically connected to the first peripheral circuit transistor and/or the second peripheral circuit transistor, and the dummy structure is not directly connected to the first peripheral circuit transistor.

### CROSS-REFERENCE TO RELATED APPLICATION

This application is based on and claims priority under 35 U.S.C. § 119 to Korean Patent Application No. 10-2023-0096409, filed on Jul. 24, 2023, in the Korean Intellectual Property Office, the disclosure of which is incorporated by reference herein in its entirety.

### BACKGROUND

The inventive concepts of the present disclosures relate to semiconductor devices, and more specifically, to semiconductor devices including a dummy wiring and a dummy via.

In electronic systems that need data storage, semiconductor devices capable of storing high-capacity data may be needed. Semiconductor devices may need to increase a degree of integration in order to meet the excellent performance and low prices demanded by consumers while increasing data storage capacity. Two-dimensional (2D) or planar semiconductor devices may be greatly affected by the level of micro pattern formation technology because a degree of integration is mainly determined by an area occupied by a unit memory cell. However, because ultra-expensive equipment may be needed for miniaturization of a pattern, the degree of integration of 2D semiconductor devices may increase but may still be limited. Accordingly, three-dimensional (3D) semiconductor memory devices including three-dimensionally arranged memory cells have been proposed.

### SUMMARY

The inventive concepts of the present disclosures may provide semiconductor devices with improved electrical characteristics and reliability.

The inventive concepts of the present disclosures may provide semiconductor devices with an improved degree of integration.

However, the problem to be solved by the inventive concepts of the present disclosures is not limited to the problems mentioned above, and other problems not mentioned may be clearly understood by those skilled in the art from the description below.

According to an aspect of the inventive concepts of the present disclosures, there is provided a semiconductor device including a peripheral circuit structure; and a cell structure on the peripheral circuit structure, wherein the peripheral circuit structure comprises: a substrate comprising a cell region, a connection region that is adjacent to the cell region, and a pad region that extends around the cell region and the connection region; a first connection structure between the substrate and the cell structure; a first peripheral circuit transistor in the cell region and/or the connection region; and a second peripheral circuit transistor in the pad region, wherein the first connection structure includes a first wiring structure and a dummy structure, the first wiring structure overlaps the cell region, the connection region, and/or the pad region in a first direction perpendicular to an upper surface of the substrate, the first wiring structure is electrically connected to the first peripheral circuit transistor and/or the second peripheral circuit transistor, the dummy structure overlaps the cell region and/or the connection region in the first direction, and the dummy structure is not directly connected to the first peripheral circuit transistor.

According to another aspect of the inventive concepts of the present disclosures, there is provided a semiconductor device including a substrate; a peripheral circuit structure in the substrate; a first connection structure on the substrate; and a second connection structure on the first connection structure, wherein the first connection structure includes a first interlayer insulating layer, a first stopper layer on the first interlayer insulating layer, and a first connection wiring and a dummy wiring in the first interlayer insulating layer, the second connection structure includes a second stopper layer, a second interlayer insulating layer on the second stopper layer, and a second connection wiring in the second interlayer insulating layer, the first connection wiring is electrically connected to the peripheral circuit structure, the dummy wiring is not directly connected to the peripheral circuit structure, an upper surface of the dummy wiring and a lower surface of the first stopper layer are coplanar with each other, and a lower surface of the second connection wiring and an upper surface of the second stopper layer are coplanar with each other.

According to another aspect of the inventive concepts of the present disclosures, there is provided a semiconductor device including a peripheral circuit structure; and a cell structure on the peripheral circuit structure, wherein the peripheral circuit structure comprises: a substrate including a cell region, a connection region that is adjacent to the cell region, and a pad region that extends around the cell region and the connection region; and a first connection structure on the substrate, wherein the cell structure comprises: gate electrodes that are spaced apart from each other in a first direction in the cell region, wherein the first direction is perpendicular to an upper surface of the substrate; a channel structure that extends in the gate electrodes in the first direction in the cell region, wherein the channel structure includes a first end and a second end, the first end is closer than the second end to the peripheral circuit structure in the first direction, and the second end is opposite side to the first end; a pad portion that extends from the gate electrodes in the connection region, wherein the pad portion is in a step shape; a first vertical conductive structure that is electrically connected to the pad portion, wherein the first vertical conductive structure extends in the pad portion in the first direction; a stack insulating layer that extends around the gate electrodes in a plan view; a second vertical conductive structure in the pad region, wherein the second vertical conductive structure extends in the stack insulating layer in the first direction; and a common source layer on the second end of the channel structure in the cell region, wherein the first connection structure includes a wiring structure and a dummy structure, the wiring structure overlaps the cell region, the connection region, and/or the pad region in the first direction, the wiring structure is electrically connected to the peripheral circuit structure, the dummy structure overlaps the cell region and/or the connection region in the first direction, and the dummy structure is not directly connected to the peripheral circuit structure.

### BRIEF DESCRIPTION OF THE DRAWINGS

Embodiments will be more clearly understood from the following detailed description taken in conjunction with the accompanying drawings in which:

FIG. 1 is a block diagram of a semiconductor device according to some embodiments;

FIG. 2 is a circuit diagram illustrating a memory block according to some embodiments;

FIG. 3 is a perspective view illustrating a representative configuration of a semiconductor device according to some embodiments;

FIG. 4 is a plan layout diagram of the semiconductor device of FIG. 3;

FIG. 5 is an enlarged layout view of portion A of FIG. 4;

FIG. 6 is a cross-sectional view taken along lines B1-B1′ and B2-B2′ of FIG. 5 according to some embodiments;

FIG. 7A is an enlarged view of portion PP1 in FIG. 6;

FIG. 7B is an enlarged view of portion PP2 in FIG. 6;

FIG. 7C is an enlarged view of portion PP3 in FIG. 6;

FIG. 8A is an enlarged view of the portion PP1 in FIG. 6;

FIG. 8B is an enlarged view of the portion PP2 in FIG. 6;

FIG. 9 is a cross-sectional view taken along the lines B1-B1′ and B2-B2′ of FIG. 5 according to some embodiments;

FIG. 10 is an enlarged view of portion PP4 of FIG. 9;

FIGS. 11 to 15 are diagrams illustrating a method of manufacturing a semiconductor device according to some embodiments, and specifically are cross-sectional views taken along the lines B1-B1′ and B2-B2′ of FIG. 5;

FIG. 16 is a diagram schematically illustrating a data storage system including a semiconductor device according to some embodiments;

FIG. 17 is a perspective view schematically illustrating a data storage system including a semiconductor device according to some embodiments; and

FIG. 18 is a diagram schematically illustrating a semiconductor package according to some embodiments, and is a cross-sectional view taken along line II-II′ of FIG. 17.

### DETAILED DESCRIPTION

Hereinafter, embodiments of the inventive concept will be described in detail with reference to the accompanying drawings.

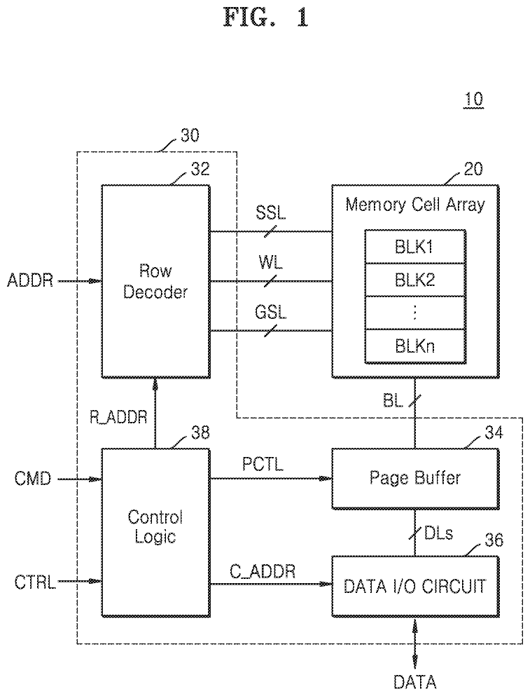

FIG. 1 is a block diagram of a semiconductor device 10 according to some embodiments.

Referring to FIG. 1, the semiconductor device 10 may include a memory cell array 20 and a peripheral circuit 30. The memory cell array 20 may include a plurality of memory cell blocks BLK1, BLK2, . . . , BLKn. The plurality of memory cell blocks BLK1, BLK2, . . . , BLKn may each include a plurality of memory cells. The plurality of memory cell blocks BLK1, BLK2, . . . , BLKn may be connected (e.g., electrically connected) to the peripheral circuit 30 through a plurality of bit lines BL, a plurality of word lines WL, a plurality of string select lines SSL, and a ground select line GSL. It will be understood that when an element or layer is referred to as being “connected to”, or “coupled to” another element or layer, it may be directly on, connected to, or coupled to the other element or layer, or one or more intervening elements or layers may be present. In contrast, when an element is referred to as being “directly coupled,” “directly connected,” or “directly responsive” to, or “directly on,” another element, there are no intervening elements present. In addition, “electrical connection” conceptually includes a physical connection and a physical disconnection. In addition, it will also be understood that when an element or layer is referred to as being “between” two elements or layers, it may be the only element or layer between the two elements or layers, or one or more intervening elements or layers may also be present.

The peripheral circuit 30 may include a row decoder 32, a page buffer 34, a data input/output circuit 36, and a control logic 38. Although not shown in FIG. 1, the peripheral circuit 30 may further include an input/output interface, column logic, a voltage generator, a pre-decoder, a temperature sensor, a command decoder, an address decoder, an amplifier circuit, etc.

The memory cell array 20 may be connected (e.g., electrically connected) to the page buffer 34 through the plurality of bit lines BL and may be connected (e.g., electrically connected) to the row decoder 32 through the plurality of word lines WL, the plurality of string select lines SSL, and the ground select line GSL. In the memory cell array 20, the memory cells included in the plurality of memory cell blocks BLK1, BLK2, . . . , BLKn may be flash memory cells. The memory cell array 20 may include a three-dimensional (3D) memory cell array. The 3D memory cell array may include a plurality of NAND strings, and each of the NAND strings may include a plurality of memory cells connected (e.g., electrically connected) to the plurality of word lines WL vertically stacked on a substrate.

The peripheral circuit 30 may receive an address ADDR, a command CMD, and a control signal CTRL from the outside of the semiconductor device 10 and may transmit and receive data to and from a device outside the semiconductor device 10. As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device.

The row decoder 32 may select at least one of the plurality of memory cell blocks BLK1, BLK2, . . . , BLKn in response to the address ADDR from the outside and may select the word line WL (among the plurality of word lines WL), the string select line SSL (among the plurality of word lines WL), and the ground select line GSL of the selected memory cell block (among the plurality of memory cell blocks BLK1, BLK2, . . . , BLKn). The row decoder 32 may transmit a voltage for performing a memory operation to the plurality of word lines WL of the selected memory cell block (among the plurality of memory cell blocks BLK1, BLK2, . . . , BLKn).

The page buffer 34 may be connected (e.g., electrically connected) to the memory cell array 20 through the plurality of bit lines BL. The page buffer 34 may operate as a write driver during a program operation to apply a voltage according to the data to be stored in the memory cell array 20 to the plurality of bit lines BL and may operate as a sense amplifier during a read operation to sense the data stored in the memory cell array 20. The page buffer 34 may operate in response to a control signal PCTL provided from the control logic 38.

The data input/output circuit 36 may be connected (e.g., electrically connected) to the page buffer 34 through a plurality of data lines DLs. The data input/output circuit 36 may receive the data from a memory controller (not shown) during a program operation, and may provide a program data to the page buffer 34 based on a column address C_ADDR provided from the control logic 38. During a read operation, the data input/output circuit 36 may provide a read data stored in the page buffer 34 to the memory controller based on the column address C_ADDR provided from the control logic 38.

The data input/output circuit 36 may transmit an address or a command which is input to the control logic 38 or the row decoder 32. The peripheral circuit 30 may further include an electrostatic discharge (ESD) circuit and a pull-up/pull-down driver.

The control logic 38 may receive the command CMD and the control signal CTRL from the memory controller. The control logic 38 may provide a row address R_ADDR to the row decoder 32 and provide the column address C_ADDR to the data input/output circuit 36. The control logic 38 may generate various internal control signals used in the semiconductor device 10 in response to the control signal CTRL. For example, the control logic 38 may adjust levels of voltages provided to the plurality of word lines WL and the plurality of bit lines BL when a memory operation, such as a program operation or an erase operation, is performed.

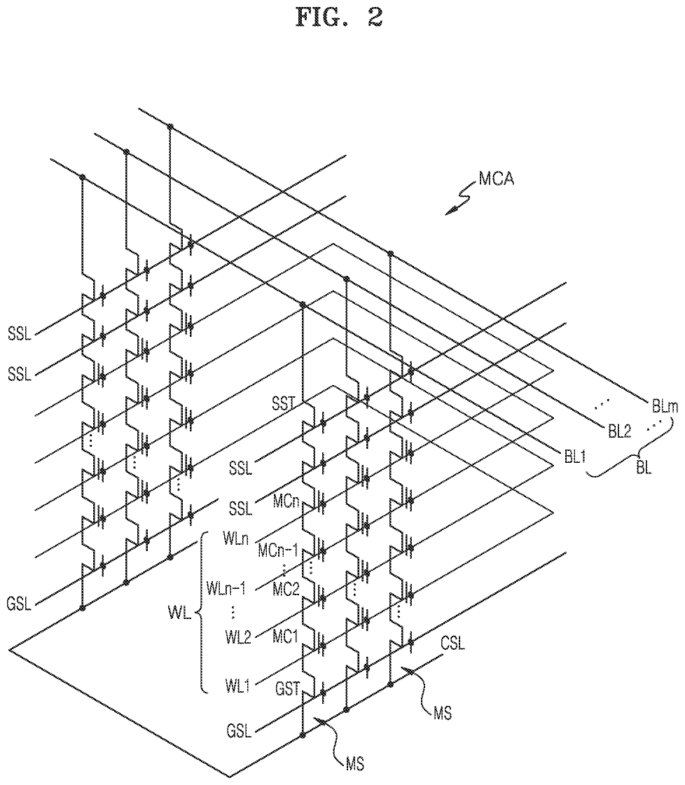

FIG. 2 is a circuit diagram illustrating a memory block BLK (among the plurality of memory cell blocks BLK1, BLK2, . . . , BLKn) according to some embodiments.

Referring to FIG. 2, the memory cell array MCA may include a plurality of memory cell strings MS. The memory cell array MCA may include a plurality of bit lines BL: BL1, BL2, . . . , BLm, a plurality of word lines WL: WL1, WL2, . . . , WLn-1, WLn, at least one string select line SSL, at least one ground select line GSL, and a common source line CSL. A plurality of memory cell strings MS may be formed between the plurality of bit lines BL: BL1, BL2, . . . , BLm and the common source line CSL. FIG. 2 illustrates that each of the plurality of memory cell strings MS includes two string select lines SSL, but the inventive concept is not limited thereto. For example, each of the plurality of memory cell strings MS may also include one string select line SSL.

Each of the plurality of memory cell strings MS may include a string select transistor SST, a ground select transistor GST, and a plurality of memory cell transistors MC1, MC2, . . . , MCn-1, MCn. A drain region of the string select transistor SST may be connected (e.g., electrically connected) to at least one of the plurality of bit lines BL: BL1, BL2, . . . , BLm, and a source region of the ground select transistor GST may be connected (e.g., electrically connected) to the common source line CSL. The common source line CSL may be connected (e.g., electrically connected) in common to source regions of a plurality of ground select transistors GST.

The string select transistor SST may be connected (e.g., electrically connected) to the string select line SSL, and the ground select transistor GST may be connected (e.g., electrically connected) to the ground select line GSL. Each of the plurality of memory cell transistors MC1, MC2, . . . , MCn-1, MCn may be respectively connected (e.g., electrically connected) to the plurality of word lines WL: WL1, WL2, . . . , WLn-1, WLn.

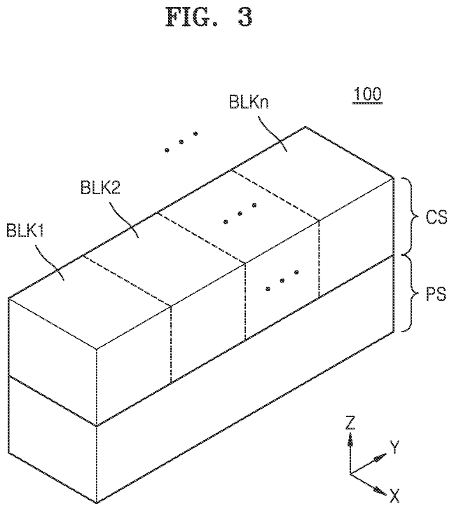

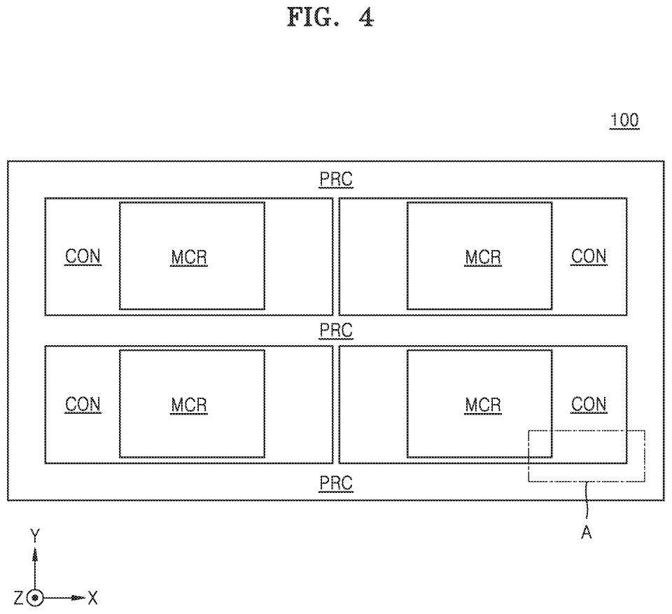

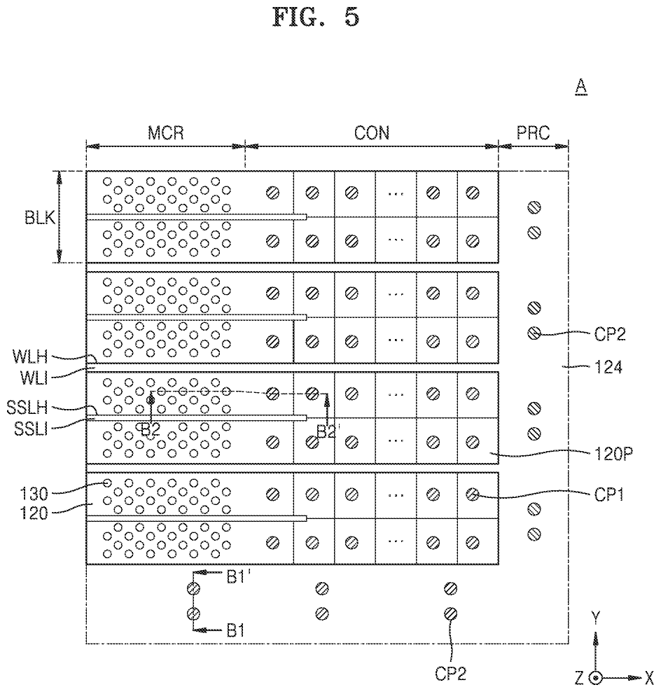

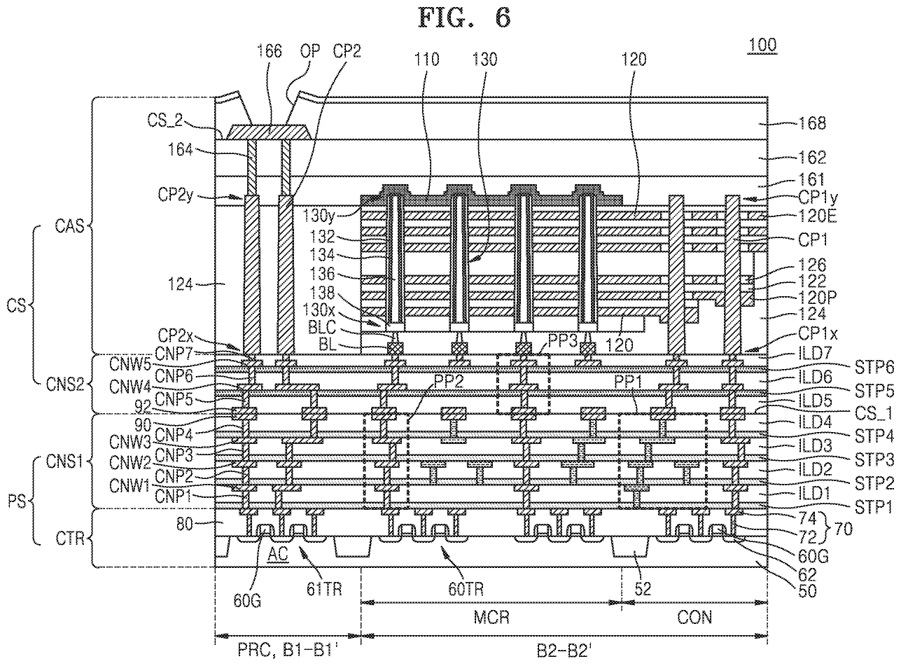

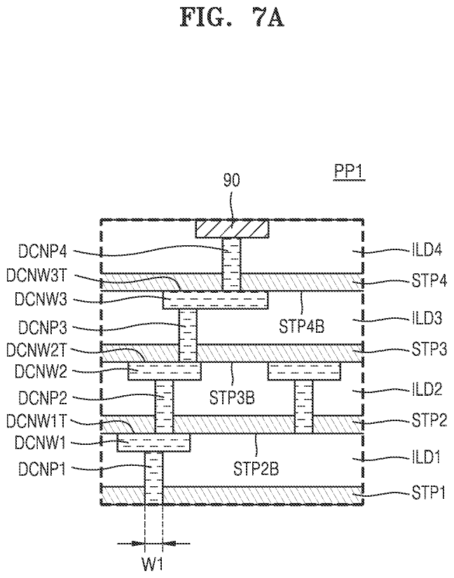

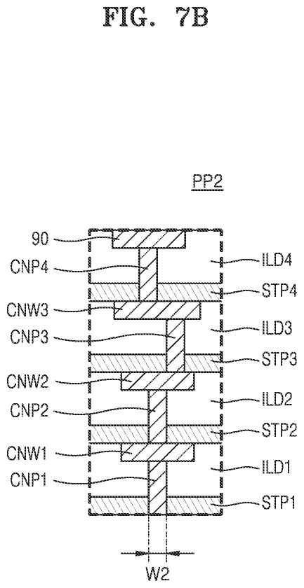

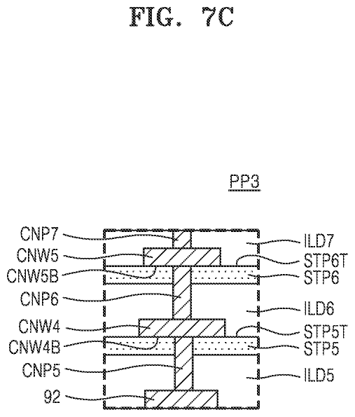

FIG. 3 is a perspective view illustrating a representative configuration of a semiconductor device 100 according to some embodiments. FIG. 4 is a plan layout diagram of the semiconductor device 100 of FIG. 3. FIG. 5 is an enlarged layout view of portion A of FIG. 4. FIG. 6 is a cross-sectional view taken along lines B1-B1′ and B2-B2′ of FIG. 5 according to some embodiments. FIG. 7A is an enlarged view of portion PP1 in FIG. 6. FIG. 7B is an enlarged view of portion PP2 in FIG. 6. FIG. 7C is an enlarged view of portion PP3 in FIG. 6.

Referring to FIGS. 3 to 7C, the semiconductor device 100 includes a cell structure CS and a peripheral circuit structure PS that overlap each other in a vertical direction Z. The cell structure CS may include the memory cell array 20 described with reference to FIG. 1, and the peripheral circuit structure PS may include the peripheral circuit 30 described with reference to FIG. 1.

In the specification, a first horizontal direction X is defined as a direction parallel to an upper surface of a substrate 50, which will be described below, a second horizontal direction Y is defined as a direction parallel to the upper surface of the substrate 50 and intersecting the first horizontal direction X, and a vertical direction Z is defined as a direction perpendicular to the upper surface of the substrate 50. The vertical direction Z may intersect the first horizontal direction X and the second horizontal direction Y.

The cell structure CS may include a plurality of memory cell blocks BLK1, BLK2, . . . , BLKn. Each of the plurality of memory cell blocks BLK1, BLK2, . . . , BLKn may include memory cells which are arranged three-dimensionally.

The peripheral circuit structure PS may include a peripheral circuit transistor structure CTR and a first connection structure CNS1 on the peripheral circuit transistor structure CTR. The peripheral circuit transistor structure CTR may include first and second peripheral circuit transistors 60TR and 61TR and a peripheral circuit wiring structure 70 disposed on (in) the substrate 50.

The substrate 50 may include a cell region MCR, a connection region CON, and a pad region PRC. As shown in FIG. 4, the connection region CON may be adjacent to (e.g., next to) the cell region MCR (in the first horizontal direction X), and the pad region PRC may extend around (e.g., surround) the cell region MCR and the connection region CON.

The substrate 50 may include a semiconductor material, for example, a group IV semiconductor, a group III-V compound semiconductor, and/or a group II-VI oxide semiconductor. For example, the group IV semiconductor may include silicon (Si), germanium (Ge), and/or silicon-germanium. The substrate 50 may be provided as a bulk wafer or an epitaxial layer. In some embodiments, the substrate 50 may include a silicon-on-insulator (SOI) substrate, or a germanium-on-insulator (GeOI) substrate.

An active region AC may be defined in the substrate 50 by a device isolation layer 52, and a plurality of the first peripheral circuit transistors 60TR and a plurality of the second peripheral circuit transistors 61TR may be formed on (in) the active region AC. The first peripheral circuit transistor 60TR may be formed in the cell region MCR and the connection region CON of the substrate 50. The second peripheral circuit transistor 61TR may be formed in the pad region PRC of the substrate 50. The plurality of the first and second peripheral circuit transistors 60TR and 61TR may each include a peripheral circuit gate 60G and source/drain regions 62 that are disposed in portions of the substrate 50 on both (e.g., opposite) sides of the peripheral circuit gate 60G.

The peripheral circuit wiring structure 70 may include a plurality of peripheral circuit contacts 72 and a plurality of peripheral circuit wirings 74. The peripheral circuit transistor structure CTR may include a peripheral circuit insulating layer 80 disposed on the substrate 50. The peripheral circuit insulating layer 80 may be disposed on (e.g., cover) the first and second peripheral circuit transistors 60TR and 61TR and the peripheral circuit wiring structure 70. Although the peripheral circuit wiring 74 is shown to include only one layer in FIG. 6, the peripheral circuit wiring 74 may have a multi-layer structure including a plurality of metal layers disposed at different vertical levels. Herein, a vertical level, a vertical height, or the like may mean a distance from the upper surface of the substrate 50 in the vertical direction Z.

The first connection structure CNS1 may include first to fourth stopper layers STP1 to STP4, first to fourth interlayer insulating layers ILD1 to ILD4, first to fourth connection vias CNP1 to CNP4, first to third connection wirings CNW1 to CNW3, first to fourth dummy vias DCNP1 to DCNP4, first to third dummy wirings DCNW1 to DCNW3, and first connection pads 90.

The first to fourth stopper layers STP1 to STP4 and the first to fourth interlayer insulating layers ILD1 to ILD4 may be alternately sequentially stacked on the substrate 50. For example, the first interlayer insulating layer ILD1 may be disposed on the first stopper layer STP1, and the second stopper layer STP2 may be disposed on the first interlayer insulating layer ILD1. In the drawing, only four interlayer insulating layers and four stopper layers are shown in the first connection structure CNS1, but the inventive concept is not limited thereto and four or more or less interlayer insulating layers and four or more or less stopper layers may be provided in the first connection structure CNS1. Thicknesses (i.e., a length in the vertical direction Z) of the first to fourth interlayer insulating layers ILD1 to ILD4 may be respectively greater than thicknesses of the first to fourth stopper layers STP1 to STP4. Each of the first to fourth interlayer insulating layers ILD1 to ILD4 may include a material having etch selectivity with each of the first to fourth stopper layers STP1 to STP4. For example, the first to fourth interlayer insulating layers ILD1 to ILD4 may each include silicon oxide, and the first to fourth stopper layers STP1 to STP4 may each include silicon nitride.

The first to third connection wirings CNW1 to CNW3 and the first to third dummy wirings DCNW1 to DCNW3 may be respectively disposed in the first to third interlayer insulating layers ILD1 to ILD3. The first to third connection wirings CNW1 to CNW3 may function as an electrical path in terms of circuit of the semiconductor device 100. On the other hand, the first to third dummy wirings DCNW1 to DCNW3 may be dummy parts unrelated to the electrical path in terms of circuit of the semiconductor device 100. For example, the first to third connection wirings CNW1 to CNW3 may be connected (e.g., electrically connected) to the first and second peripheral circuit transistors 60TR and 61TR. On the other hand, the first to third dummy wirings DCNW1 to DCNW3 may be disconnected to (e.g., electrically disconnected to, electrically insulated from, or electrically neglectable, except for the effects caused by the improved hydrogen supply, to) the first and second peripheral circuit transistors 60TR and 61TR.

The first connection wiring CNW1 and the first dummy wiring DCNW1 may be disposed in the first interlayer insulating layer ILD1. The second connection wiring CNW2 and the second dummy wiring DCNW2 may be disposed in the second interlayer insulating layer ILD2. The third connection wiring CNW3 and the third dummy wiring DCNW3 may be disposed in the third interlayer insulating layer ILD3. The first to third connection wirings CNW1 to CNW3 may be disposed on all of the cell region MCR, the connection region CON, and the pad region PRC of the substrate 50. The first to third connection wirings CNW1 to CNW3 may overlap the cell region MCR, the connection region CON, and/or the pad region PRC of the substrate 50 in the vertical direction Z.

On the other hand, the first to third dummy wirings DCNW1 to DCNW3 may be disposed on the cell region MCR and the connection region CON of the substrate 50. The first to third dummy wirings DCNW1 to DCNW3 may overlap the cell region MCR and/or the connection region CON of the substrate 50 in the vertical direction Z. The first to third dummy wirings DCNW1 to DCNW3 may not be disposed on the pad region PRC of the substrate 50. For example, the first to third dummy wirings DCNW1 to DCNW3 may not overlap the pad region PRC in the vertical direction Z.

Each of the first to third connection wirings CNW1 to CNW3 may be spaced apart from each of the first to third dummy wirings DCNW1 to DCNW3. That is, each of the first to third connection wirings CNW1 to CNW3 may be configured to be electrically separated from (e.g., electrically disconnected to or electrically insulated from) each of the first to third dummy wirings DCNW1 to DCNW3. In some embodiments, the first to fourth dummy vias DCNP1 to DCNP4 and the first to third dummy wirings DCNW1 to DCNW3 may not be directly connected to other components in the peripheral circuit wiring structure 70, such as the plurality of peripheral circuit contacts 72 and the plurality of peripheral circuit wirings 74).

The first to fourth connection vias CNP1 to CNP4 and the first to fourth dummy vias DCNP1 to DCNP4 may be respectively disposed in the first to fourth interlayer insulating layers ILD1 to ILD4. The first to fourth connection vias CNP1 to CNP4 may be disposed on all of the cell region MCR, the connection region CON, and the pad region PRC of the substrate 50. The first to fourth connection vias CNP1 to CNP4 may overlap the cell region MCR, the connection region CON, and/or the pad region PRC of the substrate 50 in the vertical direction Z. The first to fourth dummy vias DCNP1 to DCNP4 may be disposed on the cell region MCR and the connection region CON of the substrate 50. The first to fourth dummy vias DCNP1 to DCNP4 may overlap the cell region MCR and/or the connection region CON of the substrate 50 in the vertical direction Z. The first to fourth dummy vias DCNP1 to DCNP4 may not be disposed on the pad region PRC. For example, the first to fourth dummy vias DCNP1 to DCNP4 may not overlap the pad region PRC in the vertical direction Z.

The first connection via CNP1 may extend in (e.g., penetrate) the first stopper layer STP1 to be connected (e.g., electrically connected) to the peripheral circuit wiring 74, and may extend in (e.g., be inserted into) the first interlayer insulating layer ILD1 to be connected (e.g., electrically connected) to the first connection wiring CNW1. The second connection via CNP2 may extend in (e.g., penetrate) the second stopper layer STP2 to be connected (e.g., electrically connected) to the first connection wiring CNW1, and may extend in (e.g., be inserted into) the second interlayer insulating layer ILD2 to be connected (e.g., electrically connected) to the second connection wiring CNW2. The third connection via CNP3 may extend in (e.g., penetrate) the third stopper layer STP3 to be connected (e.g., electrically connected) to the second connection wiring CNW2, and may extend in (e.g., be inserted into) the third interlayer insulating layer ILD3 to be connected (e.g., electrically connected) to the third connection wiring CNW3. The fourth connection via CNP4 may extend in (e.g., penetrate) the fourth stopper layer STP4 to be connected (e.g., electrically connected) to the third connection wiring CNW3, and may extend in (e.g., be inserted into) the fourth interlayer insulating layer ILD4 to be connected (e.g., electrically connected) to any one (e.g., at least one) of the first connection pads 90.

The first dummy via DCNP1 may extend in (e.g., penetrate) the first stopper layer STP1, may extend in (e.g., be inserted into) the first interlayer insulating layer ILD1, and may be connected to the first dummy wiring DCNW1. The first dummy via DCNP1 may be spaced apart from (e.g., disconnected to, electrically disconnected to, or electrically insulated from) the peripheral circuit wiring 74. The second dummy via DCNP2 may extend in (e.g., penetrate) the second stopper layer STP2 to be connected to the first dummy wiring DCNW1, and may extend in (e.g., be inserted into) the second interlayer insulating layer ILD2 to be connected to the second dummy wiring DCNW2. The third dummy via DCNP3 may extend in (e.g., penetrate) the third stopper layer STP3 to be connected to the second dummy wiring DCNW2, and may extend in (e.g., be inserted into) the third interlayer insulating layer ILD3 to be connected to the third dummy wiring DCNW3. The fourth dummy via DCNP4 may extend in (e.g., penetrate) the fourth stopper layer STP4 to be connected to the third dummy wiring DCNW3, and may extend in (e.g., be inserted into) the fourth interlayer insulating layer ILD4 to be connected to any one of (e.g., at least one) the first connection pads 90.

The first to third connection wirings CNW1 to CNW3 and the first to fourth connection vias CNP1 to CNP4 may each include, for example, metal and/or metal nitride. The metal may include, for example, tungsten, copper, aluminum, titanium, tantalum, and/or cobalt. The first to third dummy wirings DCNW1 to DCNW3 and the first to fourth dummy vias DCNP1 to DCNP4 may respectively include, for example, the same materials as materials of the first to third connection wirings CNW1 to CNW3 and the first to fourth connection vias CNP1 to CNP4. In some embodiments, the first to third dummy wirings DCNW1 to DCNW3 and the first to fourth dummy vias DCNP1 to DCNP4 may respectively include, for example, metal materials having hydrogen diffusivity greater than that of the first to fourth stopper layers STP1 to STP4. For example, the first to third dummy wirings DCNW1 to DCNW3 and the first to fourth dummy vias DCNP1 to DCNP4 may each include tungsten and/or copper.

The first connection pads 90 may be disposed in the fourth interlayer insulating layer ILD4. An upper surface of each of the first connection pads 90 may be coplanar with an upper surface of the fourth interlayer insulating layer ILD4. Each of the first connection pads 90 may be connected to the fourth connection via CNP4 and/or the fourth dummy via DCNP4.

Referring to FIGS. 7A and 7B, the first dummy via DCNP1 may have a first width W1. The first width W1 may be the width of the first dummy via DCNP1 in the first horizontal direction X or the second horizontal direction Y. The first connection via CNP1 may have a second width W2. The second width W2 may be the width of the first connection via CNP1 in the first horizontal direction X or the second horizontal direction Y. The first width W1 may be substantially the same as the second width W2. A width of each of the second to fourth dummy vias DCNP2 to DCNP4 in the first horizontal direction X or the second horizontal direction Y may also be substantially the same as the first width W1. The width of each of the second to fourth connection vias CNP2 to CNP4 in the first horizontal direction X or the second horizontal direction Y may also be substantially the same as the second width W2.

A vertical level of an upper surface DCNW1T of the first dummy wiring DCNW1 may be substantially the same as a vertical level of a lower surface STP2B of the second stopper layer STP2. For example, the upper surface DCNW1T of the first dummy wiring DCNW1 may be coplanar with the lower surface STP2B of the second stopper layer STP2. A vertical level of an upper surface DCNW2T of the second dummy wiring DCNW2 may be substantially the same as a vertical level of a lower surface STP3B of the third stopper layer STP3. For example, the upper surface DCNW2T of the second dummy wiring DCNW2 may be coplanar with the lower surface STP3B of the third stopper layer STP3. A vertical level of an upper surface DCNW3T of the third dummy wiring DCNW3 may be substantially the same as a vertical level of a lower surface STP4B of the fourth stopper layer STP4. For example, the upper surface DCNW3T of the third dummy wiring DCNW3 may be coplanar with the lower surface STP4B of the fourth stopper layer STP4.

Referring again to FIGS. 3 to 6, the cell structure CS may be disposed on the peripheral circuit structure PS. The cell structure CS may include a second connection structure CNS2 and a cell array structure CAS on the second connection structure CNS2.

The second connection structure CNS2 may include second connection pads 92, fifth to seventh interlayer insulating layers ILD5 to ILD7, fifth and sixth stopper layers STP5 and STP6, fourth and fifth connection wirings CNW4 and CNW5, and fifth to seventh connection vias CNP5 to CNP7.

The fifth interlayer insulating layer ILD5 may be disposed on the fourth interlayer insulating layer ILD4. The second connection pads 92 may be disposed on a lower portion of the fifth interlayer insulating layer ILD5. The second connection pads 92 may be respectively connected (e.g., electrically connected) to the first connection pads 90. The fifth interlayer insulating layer ILD5 may be in contact with the fourth interlayer insulating layer ILD4. The peripheral circuit structure PS and the cell structure CS may be electrically connected to and bonded to each other by the first and second connection pads 90 and 92 and the fourth and fifth interlayer insulating layers ILD4 and ILD5.

The fifth and sixth stopper layers STP5 and STP6 and the sixth and seventh interlayer insulating layers ILD6 and ILD7 may be alternately sequentially stacked on the fifth interlayer insulating layer ILD5. For example, the fifth stopper layer STP5 may be disposed on the fifth interlayer insulating layer ILD5, and the sixth interlayer insulating layer ILD6 may be disposed on the fifth stopper layer STP5. The sixth stopper layer STP6 may be disposed on the sixth interlayer insulating layer ILD6, and the seventh interlayer insulating layer ILD7 may be disposed on the sixth stopper layer STP6. The fifth to seventh interlayer insulating layers ILD5 to ILD7 may include, for example, silicon oxide, and the fifth and sixth stopper layers STP5 and STP6 may include, for example, silicon nitride.

The fourth and fifth connection wirings CNW4 and CNW5 may be respectively disposed in the sixth and seventh interlayer insulating layers ILD6 and ILD7. The fourth connection wiring CNW4 may be disposed within a lower portion of the sixth interlayer insulating layer ILD6. The fifth connection wiring CNW5 may be disposed within a lower portion of the seventh interlayer insulating layer ILD7.

The fifth connection via CNP5 may extend in (e.g., penetrate) the fifth stopper layer STP5 to be connected (e.g., electrically connected) to the fourth connection wiring CNW4. The fifth connection via CNP5 may extend in (e.g., be inserted into) the fifth interlayer insulating layer ILD5 to be connected to any one (e.g., at least one) of the second connection pads 92. The sixth connection via CNP6 may extend in (e.g., penetrate) the sixth stopper layer STP6 to be connected (e.g., electrically connected) to the fifth connection wiring CNW5. The sixth connection via CNP6 may extend in (e.g., be inserted into) the sixth interlayer insulating layer ILD6 to be connected (e.g., electrically connected) to the fourth connection wiring CNW4. The seventh connection via CNP7 may extend in (e.g., be provided in) the seventh interlayer insulating layer ILD7 to be connected (e.g., electrically connected) to the fifth connection wiring CNW5.

In the drawing, only three interlayer insulating layers, two stopper layers, two connection wirings, and three connection vias are shown in the second connection structure CNS2, but the inventive concept is not limited to the numbers, and three or more or less interlayer insulating layers, two or more or less stopper layers, two or more or less connection wirings, and three or more or less connection vias may be provided in the second connection structure CNS2.

Referring to FIG. 7C, a vertical level of a lower surface CNW4B of the fourth connection wiring CNW4 may be substantially the same as a vertical level of an upper surface STP5T of the fifth stopper layer STP5. For example, the lower surface CNW4B of the fourth connection wiring CNW4 may be coplanar with the upper surface STP5T of the fifth stopper layer STP5. A vertical level of a lower surface CNW5B of the fifth connection wiring CNW5 may be substantially the same as a vertical level of an upper surface STP6T of the sixth stopper layer STP6. For example, the lower surface CNW5B of the fifth connection wiring CNW5 may be coplanar with the upper surface STP6T of the sixth stopper layer STP6.

A structure having the first to third connection wirings CNW1 to CNW3 and the first to fourth connection vias CNP1 to CNP4 may be referred to as a first wiring structure. A structure having the first to third dummy wirings DCNW1 to DCNW3 and the first to fourth dummy vias DCNP1 to DCNP4 may be referred to as a dummy structure. A structure having the fourth and fifth connection wirings CNW4 and CNW5 and the fifth to seventh connection vias CNP5 to CNP7 may be referred to as a second wiring structure.

Referring again to FIGS. 3 to 6, the cell region MCR may be a region where the memory block BLK (among the plurality of memory cell blocks BLK1, BLK2, . . . , BLKn) including a plurality of memory cell strings extending in the vertical direction Z is disposed. A common source layer 110, gate electrodes 120, and a channel structure 130 that extends in (e.g., penetrating) the gate electrodes 120 in the vertical direction Z and is connected (e.g., is electrically connected) to the common source layer 110 may be disposed in the cell region MCR. An extension portion 120E and a pad portion 120P connected to the gate electrode 120, and a first vertical conductive structure CPI extending in (e.g., penetrating) the extension portion 120E and the pad portion 120P and electrically connected to the pad portion 120P may be disposed in the connection region CON. The first vertical conductive structure CPI may be connected (e.g., electrically connected) to any one (e.g., at least one) of the plurality of seventh connection vias CNP7. A second vertical conductive structure CP2 extending in the vertical direction Z and electrically connected to the peripheral circuit wiring structure 70 may be disposed in the pad region PRC. The second vertical conductive structure CP2 may be connected (e.g., electrically connected) to any one (e.g., at least one) of the plurality of seventh connection vias CNP7. The second vertical conductive structure CP2 may be electrically connected to any one (e.g., at least one) of the second peripheral circuit transistors 61TR through the seventh connection via CNP7.

The cell structure CS may include a first surface CS_1 connected to (e.g., contacts) the peripheral circuit structure PS and a second surface CS_2 opposite to the first surface CS_1. In the drawing, the first surface CS_1 of the cell structure CS is shown to be disposed on a lower side of the cell structure CS, and the second surface CS_2 of the cell structure CS is shown to be disposed on an upper side of the cell structure CS. Here, for convenience, as shown in the drawing, being disposed close to the first surface CS_1 of the cell structure CS is defined as being disposed at a lower vertical level, and being disposed close to the second surface CS_2 of the cell structure CS is defined as being disposed a higher vertical level.

The gate electrodes 120 may be disposed to be spaced apart from each other in the vertical direction Z in the cell region MCR, and the gate electrodes 120 may be disposed alternately with a mold insulating layers 122. The gate electrodes 120 may extend into the connection region CON, and portions of the gate electrodes 120 disposed in the connection region CON may be referred to as the extension portions 120E. The extension portions 120E may have a horizontal length that (discretely) increases in a direction toward the second surface CS_2 of the cell structure CS (that is, in an upward direction in the drawing). The extension portions 120E may have a step shape (e.g., a reverse step shape in FIG. 6), and the pad portions 120P may be respectively connected to ends of the extension portions 120E. The pad portions 120P may each have a greater thickness in the vertical direction Z than that of each of the extension portions 120E.

Although not shown, the gate electrodes 120 may include a buried conductive layer and a conductive barrier layer extending around (e.g., surrounding) upper, lower, and side surfaces of the buried conductive layer. For example, the buried conductive layer may include metal such as tungsten, nickel, cobalt, tantalum, etc., metal silicide such as tungsten silicide, nickel silicide, cobalt silicide, tantalum silicide, etc., doped polysilicon, and/or a combination thereof. In some embodiments, the conductive barrier layer may include, for example, titanium nitride, tantalum nitride, tungsten nitride, and/or a combination thereof.

In some embodiments, the gate electrodes 120 may correspond to the ground select line GSL, the plurality of word lines WL: WL1, WL2, . . . , WLn-1, WLn, and the at least one string selection line SSL in (e.g., constituting) the memory cell string MS (among the plurality of the memory cell strings MS) (see FIG. 2). For example, an uppermost gate electrode 120 may function as the ground select line GSL, the lowermost two gate electrodes 120 may function as the string select lines SSL, and the remaining gate electrodes 120 may function as the plurality of word lines WL. Accordingly, the memory cell string MS in which the ground select transistor GST, the string select transistor SST, and the memory cell transistors MC1, MC2, . . . , MCn-1, MCn between the ground select transistor GST and the string select transistor SST are connected (e.g., electrically connected) in series may be provided. In some embodiments, at least one of the gate electrodes 120 may function as a dummy word line, but the inventive concept is not limited thereto.

A stack separation insulating layer WLI may be disposed in a stack separation opening WLH extending in the vertical direction Z through the gate electrodes 120 and the mold insulating layers 122. Although not shown, the stack separation insulating layer WLI may have an upper surface disposed at a vertical level higher than the uppermost gate electrode 120 and may protrude upward with respect to the uppermost gate electrode 120. As shown in FIG. 5, the gate electrodes 120 disposed between a pair of (adjacent) stack separation openings WLH may form one memory cell block BLK (among the plurality of memory cell blocks BLK1, BLK2, . . . , BLKn). In addition, within one memory cell block BLK, the at least one gate electrode 120 (e.g., the lowermost gate electrode 120) may be separated into two gate electrodes 120 by a string separation opening SSLH A string separation insulating layer SSLI may be disposed in the string separation opening SSLH.

A stack insulating layer 124 may be disposed on (e.g., may extend around or may surround) the gate electrodes 120, the extension portions 120E, and the pad portions 120P in the connection region CON and the pad region PRC. In a plan view, the stack insulating layer 124 may be disposed to extend around (e.g., surround) the gate electrodes 120. In the pad region PRC, an upper surface of the stack insulating layer 124 may be at the same vertical level as an upper surface of the uppermost mold insulating layer 122.

The channel structure 130 may include a first end 130x disposed closer to the peripheral circuit structure PS and a second end 130y opposite to the first end 130x. In some embodiments, the channel structure 130 may have inclined sidewalls such that a width of the first end 130x (in the first and/or second horizontal direction X and/or Y) is greater than a width of the second end 130y (in the first and/or second horizontal direction X and/or Y). The bit line BL may be electrically connected to the first end 130x of the channel structure 130 through a bit line contact BLC, and a common source layer 110 may be connected (e.g., electrically connected) to the second end 130y of the channel structure 130. The bit line BL may be connected (e.g., electrically connected) to any one (e.g., at least one) of the plurality of seventh connection vias CNP7.

The channel structure 130 may extend in (e.g., penetrate) the gate electrodes 120 and the mold insulating layers 122 to be disposed in a channel hole 130H that extends in the vertical direction Z. The channel structure 130 may include a gate insulating layer 132, a channel layer 134, a buried insulating layer 136, and a drain region 138. The channel layer 134 may have, for example, a cylindrical shape, and the gate insulating layer 132 may be disposed on an outer wall (e.g., outer sidewall) of the channel layer 134, and the buried insulating layer 136 may be disposed on an inner wall (e.g., inner sidewall) of the channel layer 134. The gate insulating layer 132 may not be disposed on an uppermost surface of the channel layer 134, for example, on an upper surface of the channel layer 134 disposed at the second end 130y of the channel structure 130.

Although not shown, the gate insulating layer 132 may have a structure that sequentially includes a tunneling dielectric layer, a charge storage layer, and a blocking dielectric layer on the outer wall (e.g., outer sidewall) of the channel layer 134. Relative thicknesses of the tunneling dielectric layer, the charge storage layer, and the blocking dielectric layer in (e.g., constituting) the gate insulating layer 132 may be modified in various ways.

The tunneling dielectric layer may include, for example, silicon oxide, hafnium oxide, aluminum oxide, zirconium oxide, tantalum oxide, etc. The charge storage layer may be a region where electrons passing through the tunneling dielectric layer from the channel layer 134 are stored, and may include, for example, silicon nitride, boron nitride, silicon boron nitride, and/or polysilicon doped with impurities. The blocking dielectric layer may include, for example, silicon oxide, silicon nitride, and/or a metal oxide having a greater dielectric constant than that of silicon oxide. The metal oxide may include, for example, hafnium oxide, aluminum oxide, zirconium oxide, tantalum oxide, and/or a combination thereof.

The common source layer 110 may be disposed on the uppermost mold insulating layer 122. The common source layer 110 may be conformally formed to be connected (e.g., electrically connected) to the second end 130y of the channel structure 130. Although not shown, the common source layer 110 may be on (e.g., cover) an upper surface of the stack separation insulating layer WLI. In a plan view, the common source layer 110 may be disposed on the entire cell region MCR. The common source layer 110 may not be provided on the connection region CON.

A vertical level of an upper surface of a portion of the common source layer 110 (e.g., a portion of the common source layer 110, which does not contact the second end 130y of the channel structure 130) may be different from a vertical level of an upper surface of the other portion of the common source layer 110 that contacts the second end 130y of the channel structure 130.

In some embodiments, the common source layer 110 may be disposed on (e.g., conformally cover) the upper surface of the channel layer 134 and the upper surface of the gate insulating layer 132. For example, the gate insulating layer 132 may be disposed at a lower vertical level than the upper surface of the channel layer 134, and accordingly, portions of the upper surface and sidewalls of the channel layer 134 may be covered by the common source layer 110 such that a sufficient contact area between the channel layer 134 and the common source layer 110 is secured.

In some embodiments, the common source layer 110 may include, for example, polysilicon, and a laser annealing process may be performed on the common source layer 110 to have a relatively large grain size and/or relatively good crystal quality.

The first vertical conductive structure CP1 disposed in the connection region CON may extend in (e.g., penetrate) the extension portions 120E and the pad portions 120P. Insulating patterns 126 may be formed at positions vertically overlapping the pad portions 120P. The insulating patterns 126 may be connected to the first vertical conductive structure CP1 and may be disposed between the first vertical conductive structure CP1 and the extension portions 120E.

In some embodiments, a first end CP1x of the first vertical conductive structure CP1 may be disposed closer to the peripheral circuit structure PS, and a second end CP1y of the first vertical conductive structure CP1 may be disposed opposite to the first end CP1x. The first vertical conductive structure CP1 may have an inclined sidewall such that a width of the first end CP1x (in the first and/or second horizontal direction X and/or Y) is greater than a width of the second end CP1y (in the first and/or second horizontal direction X and/or Y). The second end CP1y of the first vertical conductive structure CP1 may extend in (e.g., penetrate) the uppermost mold insulating layer 122, and the first upper insulating layer 161 may be on (e.g., cover) an upper surface of the second end CP1y of the first vertical conductive structure CP1.

Although not shown, in some embodiments, the first vertical conductive structure CP1 may include a conductive buried layer and a barrier layer of a small thickness extending around (e.g., surrounding) upper surface and sidewalls of the conductive buried layer. For example, the conductive buried layer may include, for example, metal such as tungsten, nickel, cobalt, tantalum, etc., a metal silicide such as tungsten silicide, nickel silicide, cobalt silicide, tantalum silicide, etc., doped polysilicon, and/or a combination thereof. The barrier layer may include, for example, titanium nitride, tantalum nitride, tungsten nitride, and/or a combination thereof.

The second vertical conductive structure CP2 may be disposed in the pad region PRC to extend in (e.g., penetrate) the stack insulating layer 124. A third end CP2x of the second vertical conductive structure CP2 may be disposed closer to the peripheral circuit structure PS, and a fourth end CP2y of the second vertical conductive structure CP2 may be disposed opposite to the third end CP2x. The second vertical conductive structure CP2 may have an inclined sidewall such that a width of the third end CP2x (in the first and/or second horizontal direction X and/or Y) is greater than a width of the fourth end CP2y (in the first and/or second horizontal direction X and/or Y). The fourth end CP2y of the second vertical conductive structure CP2 may extend in (e.g., penetrate) the uppermost mold insulating layer 122. The first upper insulating layer 161 may be disposed on (e.g., cover) an upper surface of the fourth end CP2y of the second vertical conductive structure CP2.

The bit line BL, the first vertical conductive structure CP1, and the second vertical conductive structure CP2 may be electrically connected to the peripheral circuit structure PS through the first and second connection pads 90 and 92.

A second upper insulating layer 162 may be disposed on the first upper insulating layer 161. The second upper insulating layer 162 may cover the first upper insulating layer 161. According to some embodiments, the second upper insulating layer 162 may be omitted.

Rear vias 164 extending in (e.g., penetrating) the second upper insulating layer 162 may be disposed. The rear vias 164 may further extend in the vertical direction Z to be (partially) disposed in (e.g., inserted into) the first upper insulating layer 161. The rear vias 164 may be respectively connected (e.g., electrically connected) to a plurality of second vertical conductive structures CP2.

A rear pad 166 may be disposed on the second upper insulating layer 162. The rear pad 166 may be connected (e.g., electrically connected) to the rear vias 164. A passivation layer 168 may be disposed on the second upper insulating layer 162, and an opening OP of the passivation layer 168 may expose at least a portion of an upper surface of the rear pad 166.

A process of manufacturing the semiconductor device 100 may include a process of implanting hydrogen from the second surface CS_2 of the cell structure CS of the semiconductor device 100. The reason for implanting hydrogen is to improve the operation speed characteristics and reliability of the semiconductor device 100 by eliminating a dangling bond defect on a surface of the substrate 50.

Specifically, when a pattern of the semiconductor device 100 is miniaturized and wirings thereof are stacked, a dark current problem may become worse. A dark current may mean charges accumulated without application of voltage, and may be generated by defects or a dangling bond present in the substrate 50.

The dangling bond is a defect that may occur on the surface of the substrate 50 when processing the substrate 50 through an oxidation process or an etching process and may mean a bond state (—Si—O) and (—Si—) in which the outermost electrons of atoms on the surface of the substrate 50 are not completely bonded and are separated (e.g., cut).

When electrons are separated from the dangling bond on the surface of the substrate 50, various portions of the semiconductor device 100 may be in states in which charges are likely to be generated even without application of voltage. When a large amount of dangling bonds is present on the substrate 50, a large amount of charges may be generated even without application of voltage, and the semiconductor device 100 may react as if a voltage is applied and may exhibit an abnormal behavior such as noise or the dark current. Therefore, it is necessary to remove the dangling bond defect of the substrate 50. At this time, the dangling bond defect may be resolved by combining with hydrogen. Therefore, it is necessary to sufficiently supply hydrogen into the substrate 50 in order to remove the dangling bond defect on the surface (e.g., the upper surface) of the substrate 50.

When hydrogen is implanted from the second surface CS_2 of the cell structure CS of the semiconductor device 100, hydrogen may easily reach the substrate 50 (in the pad region PRC) through the second vertical conductive structure CP2, the first to seventh connection vias CNP1 to CNP7, and the first to fifth connection wirings CNW1 to CNW5. On the other hand, in the cell region MCR and the connection region CON, because the numbers of the first to seventh connection vias CNP1 to CNP7 and the first to fifth connection wirings CNW1 to CNW5 are insufficient, hydrogen transferred from the first vertical conductive structure CP1 may not (sufficiently) reach the substrate 50. In particular, the first to sixth stopper layers STP1 to STP6 may each include a material having a low hydrogen diffusivity. In this case, there is no (or less) medium to diffuse hydrogen through the first to sixth stopper layers STP1 to STP6 so that hydrogen may not (sufficiently) reach the substrate 50. As a result, a problem may occur in which a hydrogen concentration in the cell region MCR and the connection region CON is less than in the pad region PRC.

The peripheral circuit structure PS of the semiconductor device 100 according to the inventive concepts of the present disclosures may include the first to fourth dummy vias DCNP1 to DCNP4 and first to third dummy wirings DCNW1 to DCNW3 in the cell region MCR and the connection region CON. The first to fourth dummy vias DCNP1 to DCNP4 and first to third dummy wirings DCNW1 to DCNW3 may each include a material having a greater hydrogen diffusivity than the first to sixth stopper layers STP1 to STP6. Accordingly, hydrogen may be better (more easily) supplied to the substrate 50 in the cell region MCR and the connection region CON. That is, the concentration of hydrogen supplied to the substrate 50 may be uniform in the cell region MCR, the connection region CON, and the pad region PCR. For the above reasons, the dangling bonding defect (in the cell region MCR, the connection region CON, and the pad region PCR) may be effectively resolved (by the first to fourth dummy vias DCNP1 to DCNP4 and first to third dummy wirings DCNW1 to DCNW3), and thus, the electrical characteristics and reliability of the semiconductor device 100 may be improved.

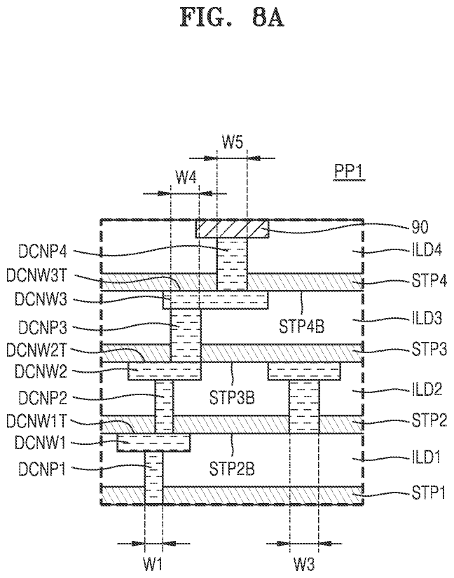

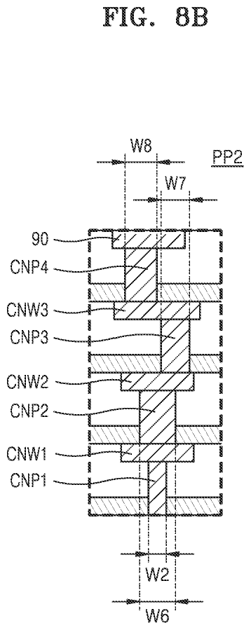

FIG. 8A is an enlarged view of the portion PP1 in FIG. 6. FIG. 8B is an enlarged view of the portion PP2 in FIG. 6. Hereinafter, descriptions redundant with those described reference to FIGS. 3 to 7C may be omitted, and only differences may be described in detail.

Referring to FIGS. 8A and 8B, the second dummy via DCNP2 may have a third width W3. The third dummy via DCNP3 may have a fourth width W4. The fourth dummy via DCNP4 may have a fifth width W5. The second connection via CNP2 may have a sixth width W6. The third connection via CNP3 may have a seventh width W7. The fourth connection via CNP4 may have an eighth width W8. The first to eighth widths W1 to W8 may be respectively widths of corresponding configurations in the first horizontal direction X or the second horizontal direction Y.

The third, fourth, and fifth widths W3, W4, and W5 may be the same as or different from the first width W1. The sixth, seventh, and eighth widths W6, W7, and W8 may be the same as or different from the second width W2. The first to eighth widths W1 to W8 may be the same as or different from each other.

In some embodiments, each of the plurality of first connection vias CNP1 may have the same width or different widths. This may also be applied to the second to fourth connection vias CNP2 to CNP4 and the first to fourth dummy vias DCNP1 to DCNP4. That is, widths of respective dummy vias may be the same as or different from each other, and widths of respective connection vias may be the same as or different from each other.

According to the inventive concepts of the present disclosures, the first width W1, third width W3, fourth width W4, and fifth width W5 of the first to fourth dummy vias DCNP1 to DCNP4 and the second width W2, sixth width W6, seventh width W7, and eighth width W8 of the first to fourth connection vias CNP1 to CNP4 may be the same as or different from each other. Through this, the width of each of the first to fourth dummy vias DCNP1 to DCNP4 and the first to fourth connection vias CNP1 to CNP4 may be increased in a portion where the hydrogen concentration is insufficient, and may be reduced in a portion where the hydrogen concentration is sufficient (e.g., excessive) for a process margin. The width of each of the first to fourth dummy vias DCNP1 to DCNP4 and the first to fourth connection vias CNP1 to CNP4 may be selectively adjusted only in the portion where the hydrogen concentration is insufficient, and thus, the semiconductor device 100 may need no additional space. Through this, a degree of integration of the semiconductor device 100 may be improved.

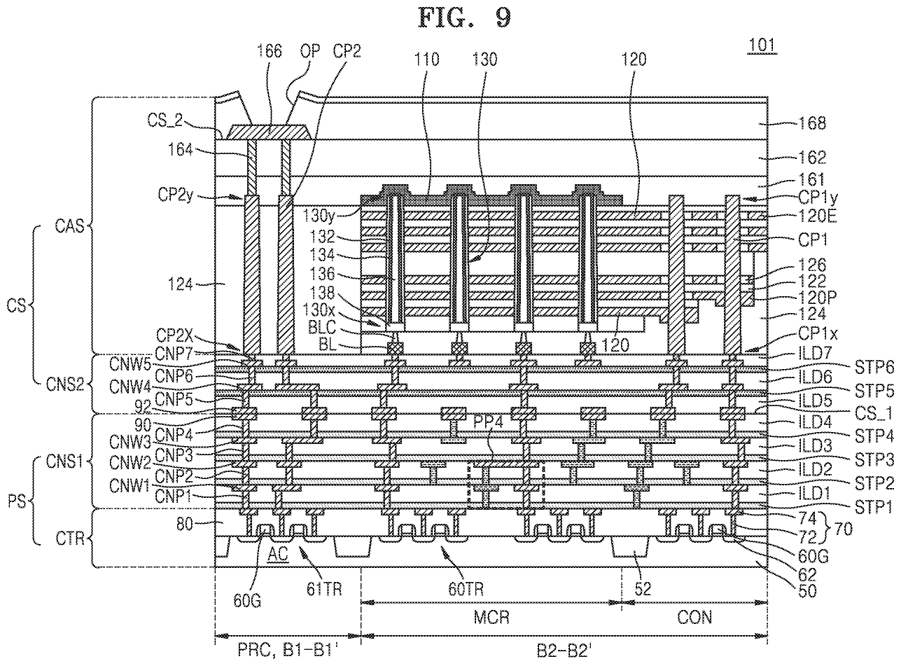

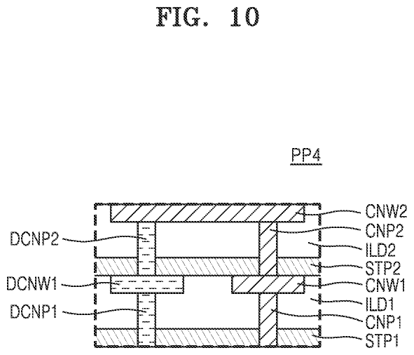

FIG. 9 is a cross-sectional view taken along the lines B1-B1′ and B2-B2′ of FIG. 5 according to some embodiments. FIG. 10 is an enlarged view of portion PP4 of FIG. 9. The semiconductor device 101 in FIG. 9 may correspond to the semiconductor device 100 in FIGS. 1 to 8B. Hereinafter, descriptions redundant with those described reference to FIGS. 3 to 7C may be omitted, and only differences may be described in detail.

Referring to FIGS. 9 and 10, at least one of the first to fourth dummy vias DCNP1 to DCNP4 may be connected to corresponding one of the first to third connection wirings CNW1 to CNW3. For example, as shown in FIG. 10, the second dummy via DCNP2may be connected to the second connection wiring CNW2. However, this only corresponds to an embodiment, and the first dummy via DCNP1 may be, for example, connected to the first connection wiring CNW1. This may vary depending on the design of the semiconductor device 101 to be implemented. In FIG. 10, the second dummy via DCNP2 may be connected to the first dummy wiring DCNW1, and the first dummy wiring DCNW1 may be connected to the first dummy via DCNP1. At this time, the dummy via DCNP1 may be separated from the peripheral circuit wiring 74. Accordingly, the second dummy via DCNP2, the first dummy wiring DCNW1, and the first dummy via DCNP1 may be electrically connected to the first peripheral circuit transistor 60TR through the second connection wiring CNW2. However, even in this case, the second dummy via DCNP2, the first dummy wiring DCNW1, and the first dummy via DCNP1 may not change an electrical path through the second connection wiring CNW2 as intended in the design of the semiconductor device 101. That is, the first to fourth dummy vias DCNP1 to DCNP4 and the first to third dummy wirings DCNW1 to DCNW3 (e.g., the second dummy via DCNP2, the first dummy wiring DCNW1, and the first dummy via DCNP1) may be only connected to the first to third connection wirings CNW1 to CNW3 (e.g., the second connection wiring CNW2) and may not be directly connected to other components in the peripheral circuit wiring structure 70, such as the plurality of peripheral circuit contacts 72 and the plurality of peripheral circuit wirings 74). For example, the second dummy via DCNP2, the first dummy wiring DCNW1, and the first dummy via DCNP1 may be electrically neglectable to the operation of the semiconductor device 101, except for the effects (improved reliability or performance of the semiconductor device 101) caused by the improved hydrogen supply by the second dummy via DCNP2, the first dummy wiring DCNW1, and the first dummy via DCNP1.

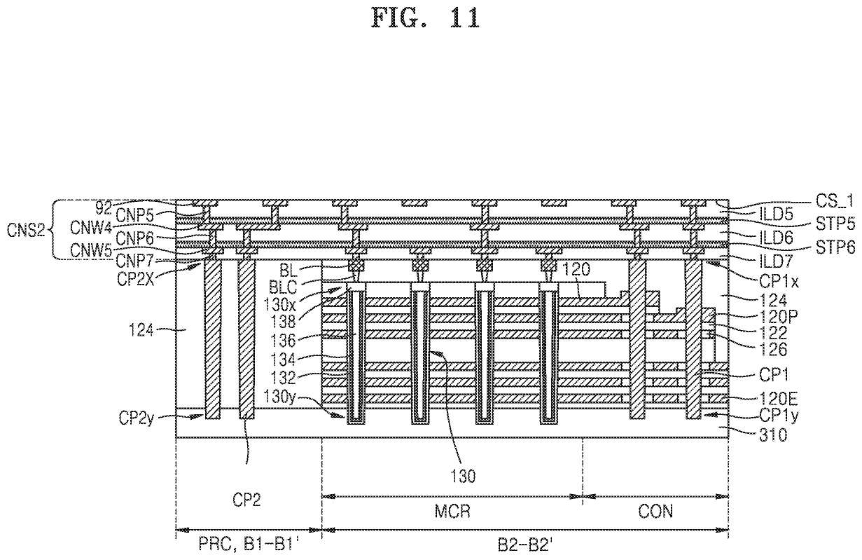

FIGS. 11 to 15 are diagrams illustrating a method of manufacturing a semiconductor device according to some embodiments, and specifically are cross-sectional views taken along the lines B1-B1′ and B2-B2′ of FIG. 5.

Referring to FIG. 11, a carrier substrate 310 including the cell region MCR, the connection region CON, and the pad region PRC may be provided. The connection region CON may be spaced apart from (or adjacent to) the cell region MCR in the first horizontal direction X, and the pad region PRC may extend around (e.g., surround) the cell region MCR and the connection region CON.

In some embodiments, the carrier substrate 310 may include, for example, silicon (Si), germanium (Ge), silicon germanium (SiGe), gallium arsenide (GaAs), indium gallium arsenide (InGaAs), aluminum gallium arsenide (AlGaAs), and/or a mixture thereof.

On the carrier substrate 310, the gate electrodes 120 and the mold insulating layers 122 may be formed in the cell region MCR and the connection region CON, and the extension portions 120E and the pad portions 120P connected to the gate electrodes 120 may be formed in the connection region CON. In addition, the channel structure 130 that extends in (e.g., penetrates) the gate electrodes 120 in the vertical direction Z and the bit line BL that is connected (e.g., electrically connected) to the channel structure 130 may be formed in the cell region MCR. In addition, the stack insulating layer 124 that is on (e.g., that extends around or that surrounds) the gate electrodes 120, the extension portions 120E, and the pad portions 120P may be formed in the connection region CON and the pad region PRC. In addition, the first vertical conductive structure CP1 that extends in (e.g., that penetrates) the extension portions 120E and the pad portions 120P in the vertical direction Z may be formed in the connection region CON, and the second vertical conductive structure CP2 that extends in (e.g., that penetrates) the stack insulating layer 124 in the vertical direction Z may be formed in the pad region PRC.

The channel structure 130, the first vertical conductive structure CP1, and the second vertical conductive structure CP2 may further extend in the vertical direction Z to be inserted into the carrier substrate 310. For example, the channel structure 130, the first vertical conductive structure CP1, and the second vertical conductive structure CP2 may at least partially penetrate the carrier substrate 310. In addition, the seventh interlayer insulating layer ILD7 may be formed on the bit line BL, the first vertical conductive structure CPI, and the second vertical conductive structure CP2. The seventh connection via CNP7 and the fifth connection wiring CNW5 that are electrically connected to the bit line BL, the first vertical conductive structure CP1, and the second vertical conductive structure CP2 may be formed. The fifth and sixth stopper layers STP5 and STP6, the fifth and sixth interlayer insulating layers ILD5 and ILD6, the fourth connection wiring CNW4, the fifth and sixth connection vias CNP5 and CNP6, and the second connection pads 92 may be formed on the seventh interlayer insulating layer ILD7.

Although not shown, the stack separation opening WLH that extends in (e.g., penetrates) the gate electrodes 120 and the mold insulating layers 122 in the vertical direction Z may be formed, and the stack separation insulating layer WLI may be formed within the stack separation opening WLH. The stack separation insulating layer WLI may further extend in the vertical direction Z to be inserted into the carrier substrate 310. For example, the stack separation insulating layer WLI may at least partially penetrate the carrier substrate 310.

In some embodiments, in a process of forming the channel structure 130, the first end 130x of the channel structure 130 may be disposed at a higher vertical level than the second end 130y, and the second end 130y may be formed to extend in (e.g., at least partially penetrate) the carrier substrate 310.

In some embodiments, in a process of forming the first vertical conductive structure CP1, the first end CP1x of the first vertical conductive structure CP1 may be formed to have a larger width than that of the second end CP1y of the vertical conductive structure CP1, and the second end CP1y of the first vertical conductive structure CP1 may be formed to extend in (e.g., at least partially penetrate) the carrier substrate 310.

In some embodiments, in a process of forming the second vertical conductive structure CP2, the third end CP2x of the second vertical conductive structure CP2 may be formed to have a larger width than the fourth end CP2y of the second vertical conductive structure CP2, and the fourth end CP2y of the second vertical conductive structure CP2 may be formed to extend in (e.g., at least partially penetrate) the carrier substrate 310.

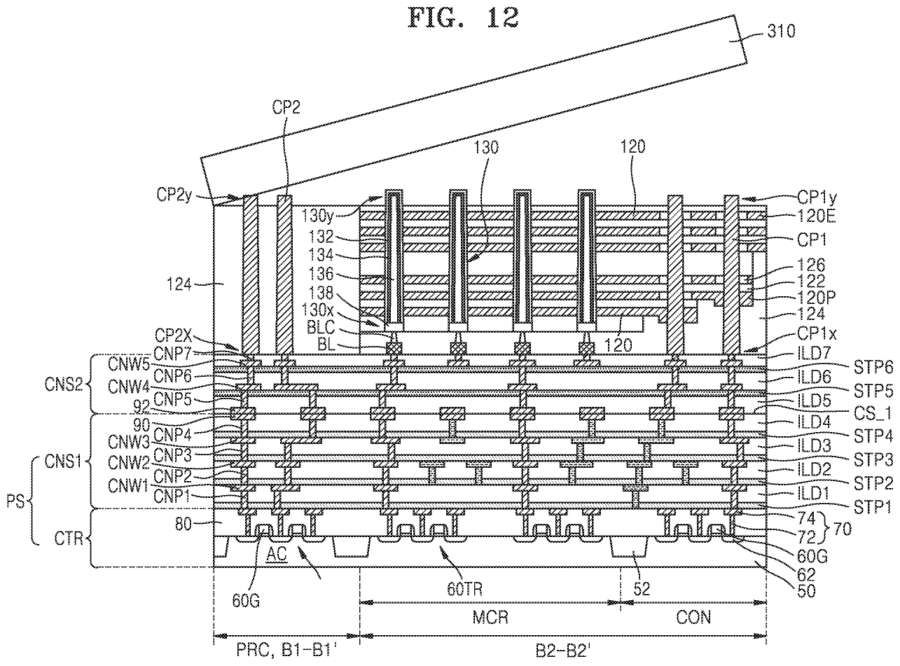

Referring to FIG. 12, the peripheral circuit structure PS may be prepared. The peripheral circuit structure PS may include the peripheral circuit transistor structure CTR and the first connection structure CNS1 on the peripheral circuit transistor structure CTR. The peripheral circuit transistor structure CTR may include the substrate 50, the first and second peripheral circuit transistors 60TR and 61TR disposed in (on) the substrate 50, and the peripheral circuit wiring structure 70. The active region AC may be defined in the substrate 50 by the device isolation layer 52, and the plurality of the first peripheral circuit transistor 60TR and the plurality of the second peripheral circuit transistors 61TR may be formed in (on) the active region AC. The plurality of the first and second peripheral circuit transistors 60TR and 61TR may each include the peripheral circuit gate 60G and the source/drain regions 62 that are disposed in portions of the substrate 50 on both (e.g., opposite) sides of the peripheral circuit gate 60G. The first connection structure CNS1 may include components included in the first connection structure CNS1 described with reference to FIGS. 3 to 6.

At this time, when the first to third dummy wirings DCNW1 to DCNW3 and the first to fourth dummy vias DCNP1 to DCNP4 include the same materials as the first to third connection wirings CNW1 to CNW3 and the first to fourth connection vias CNP1 to CNP4, no additional process is required and only the layout may be changed. Therefore, the process may be simplified.

Thereafter, the peripheral circuit structure PS may be attached to the cell structure CS. The peripheral circuit structure PS and the cell structure CS may be attached to each other by using a metal-oxide hybrid bonding method through the first connection pads 90, the second connection pads 92, the fourth interlayer insulating layer ILD4, and the fifth interlayer insulating layer ILD5, but is not limited thereto.

Thereafter, the structure where the peripheral circuit structure PS and the cell structure CS are attached to each other may be turned over so that the carrier substrate 310 faces upward. The carrier substrate 310 may be removed by, for example, a grinding process and a subsequent etching process. The second end 130y of the channel structure 130 may be exposed. Likewise, as the carrier substrate 310 is removed, the second end CP1y of the first vertical conductive structure CP1 and the fourth end CP2y of the second vertical conductive structure CP2 may be exposed. Although not shown, as the carrier substrate 310 is removed, an upper portion of the stack separation insulating layer WLI may also be exposed.

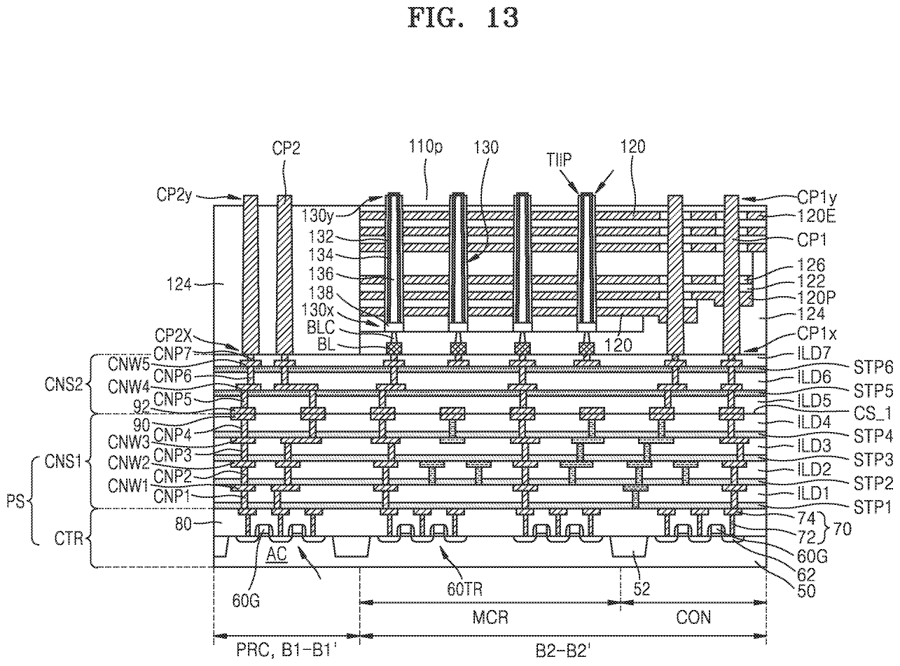

Referring to FIG. 13, an upper surface of the channel layer 134 may be exposed by removing a portion of the gate insulating layer 132 exposed at the second end 130y of the channel structure 130. In some embodiments, an upper side of the gate insulating layer 132 may be further removed so that an upper surface of the gate insulating layer 132 is disposed at a lower level than the upper surface of the channel layer 134, and portions of the upper surface and sidewalls of the channel layer 134 are exposed.

Thereafter, a tilt ion implantation process (TIIP) may be performed on the channel layer 134. The TIIP means performing an ion implantation process at an angle tilted relative to the vertical direction Z. In the TIIP, impurities of a first conductivity type may be implanted into the channel layer 134. The first conductivity type may include a P type, for example, but is not limited thereto.

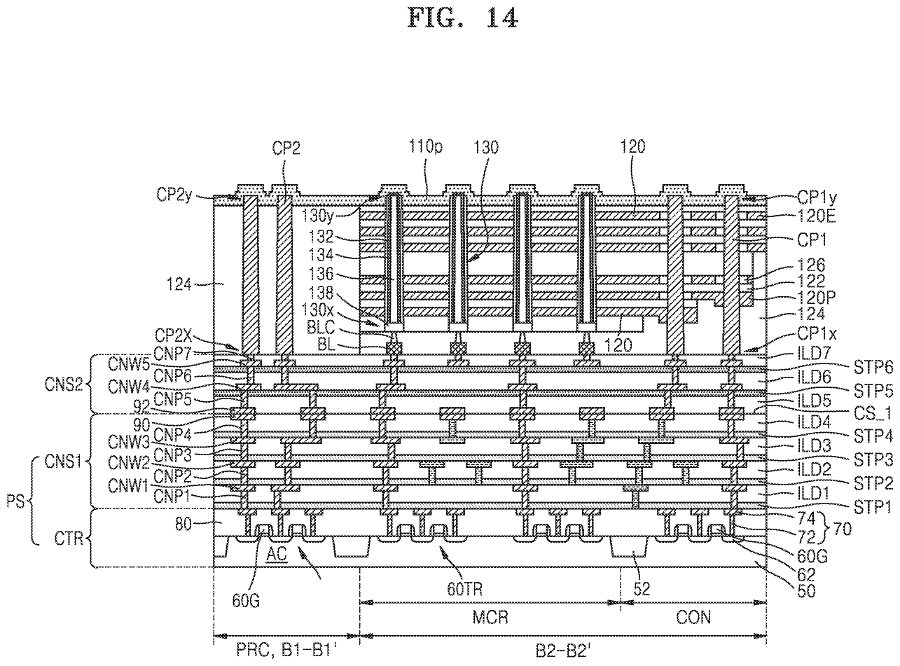

Referring to FIG. 14, a preliminary common source layer 110p may be formed on the cell region MCR, the connection region CON, and the pad region PRC. The preliminary common source layer 110p may include polysilicon.

In the cell region MCR, the preliminary common source layer 110p may be conformally formed on the uppermost one of the mold insulating layers 122 and the exposed upper surface of the channel layer 134. The preliminary common source layer 110p may be formed on the stack insulating layer 124, the first vertical conductive structure CP1, and the second vertical conductive structure CP2 in the connection region CON and the pad region PRC.

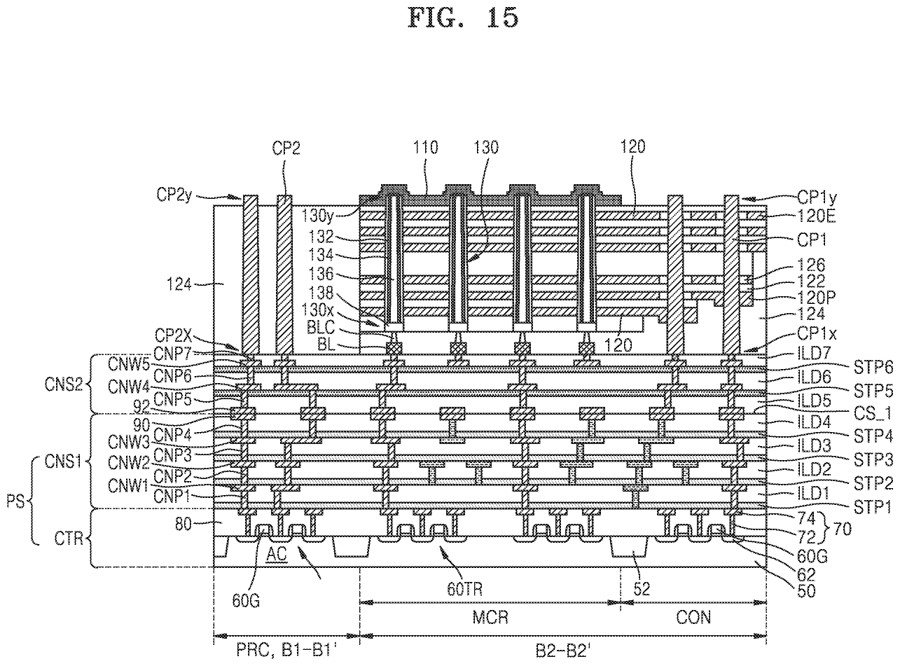

Referring to FIG. 15, an ion implantation process may be performed on the preliminary common source layer 110p by using a photo mask layer. Thereafter, the preliminary common source layer 110p may be removed from the connection region CON and the pad region PRC. Accordingly, the common source layer 110 may be formed on the cell region MCR.

Thereafter, a laser annealing process may be performed on the common source layer 110. In some embodiments, the laser annealing process may be performed to improve the crystallinity of the common source layer 110 disposed in the cell region MCR, increase the grain size of the common source layer 110, or reduce the resistance (and/or resistivity) of the common source layer 110. In some embodiments, the laser annealing process may be performed on the preliminary common source layer 110p before performing the ion implantation process.

Referring again to FIGS. 5 and 6, the first upper insulating layer 161 on (e.g., covering) the common source layer 110 may be formed. The first upper insulating layer 161 may be on (e.g., cover) the uppermost one of the mold insulating layers 122 and the second end CP1y of the first vertical conductive structure CP1 on the connection region CON. The first upper insulating layer 161 may cover the stack insulating layer 124 and the fourth end CP2y of the second vertical conductive structure CP2 on the pad region PRC.

The second upper insulating layer 162 may be formed on the first upper insulating layer 161. Forming the second upper insulating layer 162 may be omitted. The second upper insulating layer 162 may cover the first upper insulating layer 161. Thereafter, the rear vias 164 extending in (e.g., penetrating) the second upper insulating layer 162 may be formed. Each of the rear vias 164 may be disposed to be connected (e.g., electrically connected) to the second vertical conductive structure CP2.

The rear pads 166 connected (e.g., electrically connected) to the rear vias 164 may be formed on the second upper insulating layer 162. Thereafter, the passivation layer 168 on (e.g., at least partially covering) the rear pads 166 may be formed on the second upper insulating layer 162, and the opening OP may be formed in the passivation layer 168 to expose (portions of) upper surfaces of the rear pads 166. Accordingly, the semiconductor device 100 may be manufactured.

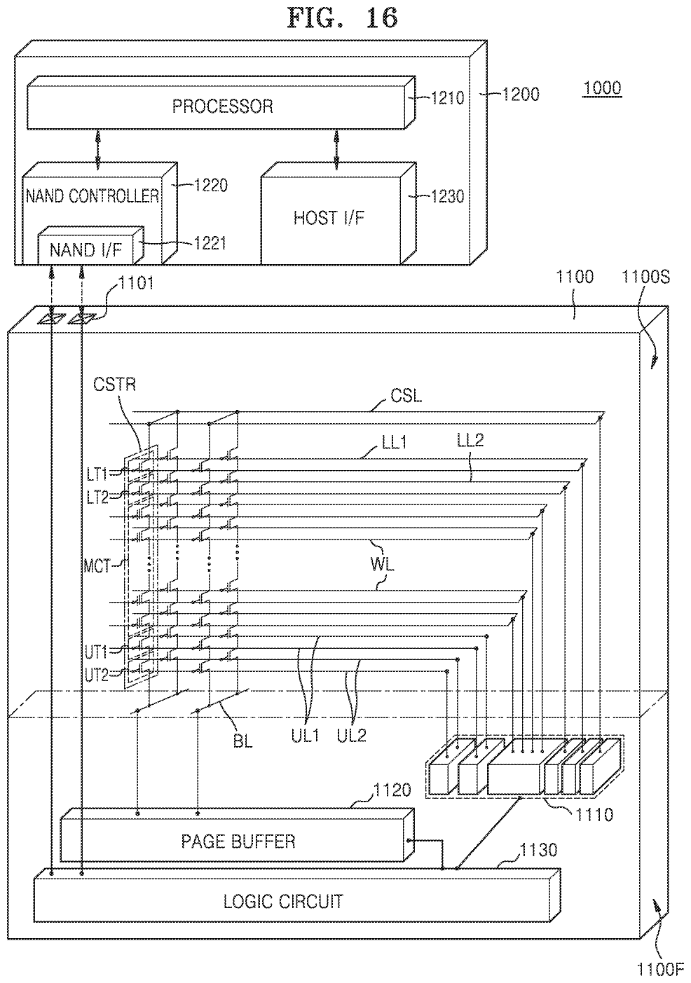

FIG. 16 is a diagram schematically illustrating a data storage system 1000 including a semiconductor device according to some embodiments.

Referring to FIG. 16, the data storage system 1000 may include one or a plurality of semiconductor devices 1100 and a memory controller 1200 electrically connected to the semiconductor device 1100. For example, the data storage system 1000 may be, for example, a solid state drive (SSD) device including at least one semiconductor device 1100, a universal serial bus (USB), a computing system, a medical device, or a communication device.

The semiconductor device 1100 may be a nonvolatile memory device. For example, the semiconductor device 1100 may be a NAND flash semiconductor device including one of the semiconductor devices 10, 100, and 101 described above with reference to FIGS. 1 to 9. The semiconductor device 1100 may include a first structure 1100F and a second structure 1100S on the first structure 1100F. The first structure 1100F may be a peripheral circuit structure PS in FIG. 3 including a row decoder 1110, a page buffer 1120, and a logic circuit 1130.

The second structure 1100S may be the memory cell structure CS in FIG. 3 including a plurality of bit lines BL, a common source line CSL, a plurality of word lines WL, first and second string select lines UL1 and UL2, first and second ground select lines LL1 and LL2, and a plurality of memory cell strings CSTR between the plurality of bit lines BL and the common source line CSL.

In the second structure 1100S, the plurality of memory cell strings CSTR may each include ground select transistors LT1 and LT2 adjacent to the common source line CSL, string select transistors UT1 and UT2 adjacent to the bit line BL, and a plurality of memory cell transistors MCT between the ground select transistors LT1 and LT2 and the string select transistors UT1 and UT2. The number of ground select transistors LT1 and LT2 and the number of string select transistors UT1 and UT2 may be modified in various ways according to embodiments.

In some embodiments, a plurality of the first ground select line LL1 and a plurality of the second ground select line LL2 may be respectively connected (e.g., electrically connected) to gate electrodes of the ground select transistors LT1 and LT2. The word line WL may be connected (e.g., electrically connected) to the gate electrode of the memory cell transistor MCT. A plurality of the first string select line UL1 and the second string select line UL2 may be respectively connected (e.g., electrically connected) to gate electrodes of the string select transistors UT1 and UT2.

The common source line CSL, the plurality of the first and second ground select lines LL1 and LL2, the plurality of word lines WL, and the plurality of the first and second string select lines UL1 and UL2 may be connected (e.g., electrically connected) to the row decoder 1110. The plurality of bit lines BL may be electrically connected to the page buffer 1120.

The semiconductor device 1100 may communicate with the memory controller 1200 through input/output pads 1101 electrically connected to the logic circuit 1130. The input/output pads 1101 may be electrically connected to the logic circuit 1130.

The memory controller 1200 may include a processor 1210, a NAND controller 1220, and a host interface 1230. In some embodiments, the data storage system 1000 may include a plurality of semiconductor devices 1100, and in this case, the memory controller 1200 may control the plurality of semiconductor devices 1100.

The processor 1210 may control all operations of the data storage system 1000 including the memory controller 1200. The processor 1210 may operate according to certain firmware and may access the semiconductor device 1100 by controlling the NAND controller 1220. The NAND controller 1220 may include a NAND interface 1221 that communicates with the semiconductor device 1100. A control command for controlling the semiconductor device 1100, data to be written to the plurality of memory cell transistors MCT of the semiconductor device 1100, and data to be read from the plurality of memory cell transistors MCT of the semiconductor device 1100, etc. may be transmitted through the NAND interface 1221. The host interface 1230 may provide a communication function between the data storage system 1000 and an external host. When receiving the control command from the external host through the host interface 1230, the processor 1210 may control the semiconductor device 1100 in response to the control command.

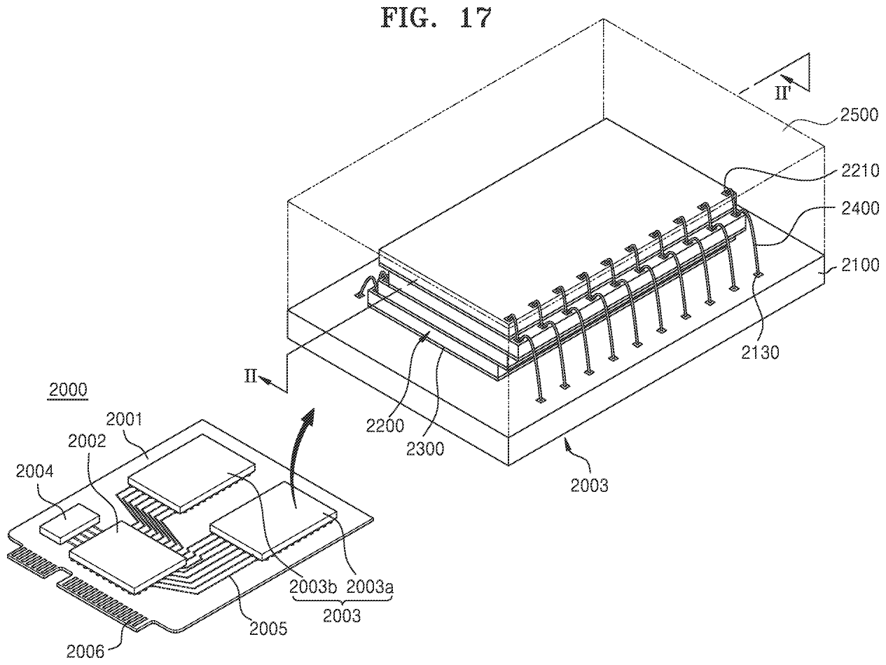

FIG. 17 is a perspective view schematically illustrating a data storage system 2000 including a semiconductor device according to some embodiments.

Referring to FIG. 17, the data storage system 2000 according to some embodiments may include a main substrate 2001, a memory controller 2002 mounted on the main substrate 2001, one or more semiconductor packages 2003, and dynamic random access memory (DRAM) 2004. The one or more semiconductor packages 2003 and the DRAM 2004 may be connected (e.g., electrically connected) to the memory controller 2002 through a plurality of wiring patterns 2005 formed on the main substrate 2001.

The main substrate 2001 may include a connector 2006 including a plurality of pins coupled to an external host. The number and arrangement of the plurality of pins in the connector 2006 may change according to a communication interface between the data storage system 2000 and the external host. In some embodiments, the data storage system 2000 may communicate with the external host according to any one of interfaces, such as universal serial bus (USB), peripheral component interconnect express (PCI-Express), serial advanced technology attachment (SATA), M-Phy for universal flash storage (UFS), etc. In some embodiments, the data storage system 2000 may be operated by power supplied from the external host through the connector 2006. The data storage system 2000 may further include a power management integrated circuit (PMIC) that distributes the power supplied from the external host to the memory controller 2002 and the one or more semiconductor packages 2003.

The memory controller 2002 may write data to the one or more semiconductor packages 2003 or read data from the one or more semiconductor packages 2003 and may improve an operating speed of the data storage system 2000.

The DRAM 2004 may be a buffer memory reducing a speed difference between the one or more semiconductor packages 2003, which are a data storage space, and the external host. The DRAM 2004 included in the data storage system 2000 may operate as a kind of cache memory and may provide a space temporarily storing data in a control operation on the one or more semiconductor packages 2003. When the data storage system 2000 includes the DRAM 2004, the memory controller 2002 may further include a DRAM controller controlling the DRAM 2004 in addition to the NAND controller controlling the one or more semiconductor packages 2003.

The one or more semiconductor packages 2003 may include first and second semiconductor packages 2003a and 2003b separated from each other. The first and second semiconductor packages 2003a and 2003b may each include a plurality of semiconductor chips 2200. Each of the first and second semiconductor packages 2003a and 2003b may include a package substrate 2100, the plurality of semiconductor chips 2200 on the package substrate 2100, an adhesive layer 2300 on a lower surface of each of the plurality of semiconductor chips 2200, a connection structure 2400 electrically connecting the plurality of semiconductor chips 2200 to the package substrate 2100, and a molding layer 2500 that is disposed on (e.g., covering) the plurality of semiconductor chips 2200 and the connection structure 2400 on the package substrate 2100.

The package substrate 2100 may be a printed circuit board including a plurality of package upper pads 2130. Each of the plurality of semiconductor chips 2200 may include input/output pads 2210. The input/output pads 2210 may correspond to the input/output pads 1101 of FIG. 16. Each of the plurality of semiconductor chips 2200 may include at least one of the semiconductor devices 10, 100, and 101 described above with reference to FIGS. 1 to 9.

In some embodiments, the connection structure 2400 may include bonding wirings respectively electrically connecting the input/output pads 2210 to the package upper pads 2130. Accordingly, in the first and second semiconductor packages 2003a and 2003b, the plurality of semiconductor chips 2200 may be electrically connected to each other by using a bonding wiring method and may be electrically connected to the package upper pads 2130 of the package substrate 2100. In some embodiments, in the first and second semiconductor packages 2003a and 2003b, the plurality of semiconductor chips 2200 may be electrically connected to each other by a connection structure including through silicon vias (TSVs) instead of the connection structure 2400 of a bonding wiring type.

In some embodiments, the memory controller 2002 and the plurality of semiconductor chips 2200 may be included in one package. In some embodiments, the memory controller 2002 and the plurality of semiconductor chips 2200 may be mounted on a separate interposer substrate different from the main substrate 2001, and the memory controller 2002 may be connected (e.g., electrically connected) to the plurality of semiconductor chips 2200 by wirings formed on the interposer substrate.

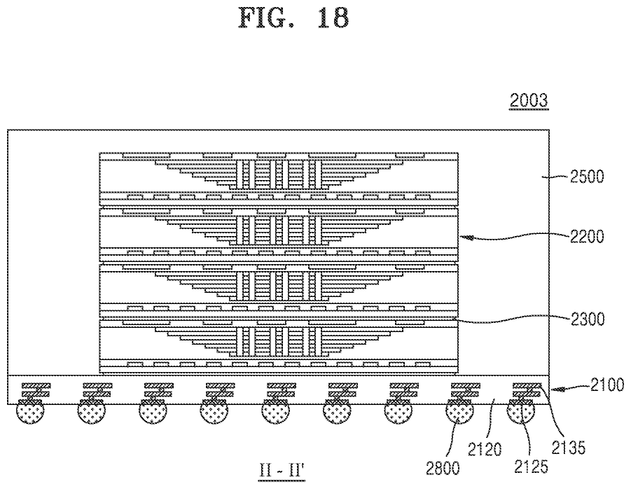

FIG. 18 is a diagram schematically illustrating the semiconductor package 2003 according to some embodiments, and is a cross-sectional view taken along line II-II′ of FIG. 17.

Referring to FIG. 18, the package substrate 2100 of the semiconductor package 2003 may be a printed circuit board. The package substrate 2100 may include a package substrate body 2120, the plurality of package upper pads 2130 (see FIG. 17) on an upper surface of the package substrate body 2120, a plurality of package lower pads 2125 arranged on a lower surface of the package substrate body 2120 or exposed through the lower surface, and a plurality of internal wirings 2135 electrically connecting the plurality of package upper pads 2130 (see FIG. 17) to the plurality of package lower pads 2125 in the package substrate body 2120. As shown in FIG. 18, the plurality of package upper pads 2130 may be respectively electrically connected to the plurality of connection structures 2400. As shown in FIG. 18, the plurality of package lower pads 2125 may be connected (e.g., electrically connected) to the plurality of wiring patterns 2005 on the main substrate 2001 of the data storage system 2000 shown in FIG. 17 through the plurality of conductive connection portions 2800. Each of the plurality of semiconductor chips 2200 may include at least one of the semiconductor devices 10, 100, and 101 described above with reference to FIGS. 1 to 9.

While the inventive concepts of the present disclosures have been particularly shown and described with reference to embodiments thereof, it will be understood that various changes in form and details may be made therein without departing from the scope of the following claims.

What is claimed is:

1. A semiconductor device comprising:
a peripheral circuit structure; and
a cell structure on the peripheral circuit structure,
wherein the peripheral circuit structure comprises:
a substrate comprising a cell region, a connection region that is adjacent to the cell region, and a pad region that extends around the cell region and the connection region;
a first connection structure between the substrate and the cell structure;
a first peripheral circuit transistor in the cell region and/or the connection region; and
a second peripheral circuit transistor in the pad region,
wherein the first connection structure includes a first wiring structure and a dummy structure,
the first wiring structure overlaps the cell region, the connection region, and/or
the pad region in a first direction perpendicular to an upper surface of the substrate,
the first wiring structure is electrically connected to the first peripheral circuit transistor and/or the second peripheral circuit transistor,
the dummy structure overlaps the cell region and/or the connection region in the first direction, and
the dummy structure is not directly connected to the first peripheral circuit transistor.

2. The semiconductor device of claim 1, wherein the cell structure includes a vertical conductive structure in the pad region, and
the vertical conductive structure is electrically connected to the second peripheral circuit transistor through the first wiring structure.

3. The semiconductor device of claim 1, wherein the dummy structure and the first wiring structure are spaced apart and electrically insulated from each other.

4. The semiconductor device of claim 1, wherein the dummy structure is connected to the first wiring structure.

5. The semiconductor device of claim 1, wherein the cell structure includes gate electrodes that are spaced apart from each other in the first direction on the upper surface of the substrate; and
a channel structure that extends in the gate electrodes,
wherein the channel structure includes a first end and a second end that is an opposite side to the first end,
the first end is closer than the second end to the peripheral circuit structure in the first direction,
a width of the first end in a second direction is greater than a width of the second end in the second direction, and
the second direction is parallel with the upper surface of the substrate.

6. The semiconductor device of claim 1, wherein
the first connection structure further includes first connection pads, and
the cell structure includes second connection pads respectively in contact with the first connection pads on the first connection structure.

7. The semiconductor device of claim 6, wherein the dummy structure is connected to the first connection pads.

8. The semiconductor device of claim 7, wherein
the cell structure further includes a second wiring structure that is electrically connected to the second connection pads, and
the first wiring structure is electrically connected to the first connection pads.

9. The semiconductor device of claim 1, wherein the first wiring structure includes:
a first connection wiring that extends in a second direction that is parallel with the upper surface of the substrate; and
a first connection via that is electrically connected to the first connection wiring and extends in the first direction, and
wherein the dummy structure includes:
a dummy wiring that extends in the second direction; and
a dummy via that is connected to the dummy wiring and extends in the first direction.

10. The semiconductor device of claim 9, wherein a width of the first connection via in the second direction and a width of the dummy via in the second direction are different from each other.

11. The semiconductor device of claim 9, wherein
the first wiring structure further includes:
a second connection wiring that extends in the second direction and is electrically connected to the first connection via; and
a second connection via that extends in the first direction and is electrically connected to the second connection wiring, and
wherein a width of the first connection via in the second direction and a width of the second connection via in the second direction are different from each other.

12. The semiconductor device of claim 9, wherein
the dummy via includes multi-layer dummy vias,
the multi-layer dummy vias are at different distances from the upper surface of the substrate, and
widths of the multi-layer dummy vias in the second direction are different from each other.

13. A semiconductor device comprising:
a substrate;
a peripheral circuit structure in the substrate;
a first connection structure on the substrate; and
a second connection structure on the first connection structure,
wherein the first connection structure includes a first interlayer insulating layer, a first stopper layer on the first interlayer insulating layer, and a first connection wiring and a dummy wiring in the first interlayer insulating layer,
the second connection structure includes a second stopper layer, a second interlayer insulating layer on the second stopper layer, and a second connection wiring in the second interlayer insulating layer,
the first connection wiring is electrically connected to the peripheral circuit structure,
the dummy wiring is not directly connected to the peripheral circuit structure,
an upper surface of the dummy wiring and a lower surface of the first stopper layer are coplanar with each other, and
a lower surface of the second connection wiring and an upper surface of the second stopper layer are coplanar with each other.

14. The semiconductor device of claim 13, wherein the dummy wiring includes a first material that has a greater hydrogen diffusivity than a second material of the first stopper layer and the second stopper layer.

15. The semiconductor device of claim 13, wherein the dummy wiring and the first connection wiring include a same material.

16. The semiconductor device of claim 13, wherein the first connection structure further includes
a dummy via that is connected to the dummy wiring and extends in the first stopper layer; and
a connection via that is electrically connected to the first connection wiring and extends in the first stopper layer.

17. The semiconductor device of claim 16, wherein a width of the dummy via in a first direction and a width of the connection via in the first direction are different from each other, and
the first direction is parallel with an upper surface of the substrate.

18. The semiconductor device of claim 13, wherein the dummy wiring is connected to the first connection wiring.

19. A semiconductor device comprising:
a peripheral circuit structure; and
a cell structure on the peripheral circuit structure,
wherein the peripheral circuit structure comprises:
a substrate including a cell region, a connection region that is adjacent to the cell region, and a pad region that extends around the cell region and the connection region; and
a first connection structure on the substrate,
wherein the cell structure comprises:
gate electrodes that are spaced apart from each other in a first direction in the cell region, wherein the first direction is perpendicular to an upper surface of the substrate;
a channel structure that extends in the gate electrodes in the first direction in the cell region, wherein the channel structure includes a first end and a second end, the first end is closer than the second end to the peripheral circuit structure in the first direction, and the second end is opposite side to the first end;
a pad portion that extends from the gate electrodes in the connection region, wherein the pad portion is in a step shape;
a first vertical conductive structure that is electrically connected to the pad portion, wherein the first vertical conductive structure extends in the pad portion in the first direction;
a stack insulating layer that extends around the gate electrodes in a plan view;
a second vertical conductive structure in the pad region, wherein the second vertical conductive structure extends in the stack insulating layer in the first direction; and
a common source layer on the second end of the channel structure in the cell region,
wherein the first connection structure includes a wiring structure and a dummy structure,
the wiring structure overlaps the cell region, the connection region, and/or the pad region in the first direction,
the wiring structure is electrically connected to the peripheral circuit structure,
the dummy structure overlaps the cell region and/or the connection region in the first direction, and
the dummy structure is not directly connected to the peripheral circuit structure.

20. The semiconductor device of claim 19, wherein
the wiring structure is electrically connected to the second vertical conductive structure in the pad region, and
the dummy structure and the wiring structure are spaced apart and electrically separated from each other.
